(19) United States
(12) Patent Application Publication
(10) Pub. No.: US 2020/0279804 A1
(43) Pub. Date: Sep. 3, 2020

(54) WIRING STRUCTURE AND METHOD FOR MANUFACTURING THE SAME

(71) Applicant: Advanced Semiconductor Engineering, Inc., Kaohsiung (TW)

(72) Inventors: Wen Hung HUANG, Kaohsiung (TW); Huei-Shyong CHO, Kaohsiung (TW); Jhao-Yang CHEN, Kaohsiung (TW)

(73) Assignee: Advanced Semiconductor Engineering, Inc., Kaohsiung (TW)

(21) Appl. No.: 16/289,156

(22) Filed: Feb. 28, 2019

(51) Int. Cl. H01L 23/522; H01L 25/16; H01L 23/00; H01L 23/528; H01L 21/66; H01L 21/768

(52) U.S. Cl. CPC H01L 23/5226; H01L 25/16; H01L 24/17; H01L 24/24; H01L 24/32; H01L 2224/73217; H01L 23/5283; H01L 22/14; H01L 21/76838; H01L 2224/73203; H01L 2224/73209; H01L 24/73

(57) ABSTRACT

A wiring structure includes an upper conductive structure, a lower conductive structure, an intermediate layer and at least one lower through via. The upper conductive structure includes at least one upper dielectric layer and at least one upper circuit layer in contact with the upper dielectric layer. The lower conductive structure includes at least one lower dielectric layer and at least one lower circuit layer in contact with the lower dielectric layer. The intermediate layer is disposed between the upper conductive structure and the lower conductive structure and bonds the upper conductive structure and the lower conductive structure together. The lower through via extends through at least a portion of the lower conductive structure and the intermediate layer, and is electrically connected to the upper circuit layer of the upper conductive structure.

### BACKGROUND

### 1. Field of the Disclosure

The present disclosure relates to a wiring structure and a manufacturing method, and to a wiring structure including at least two conductive structures attached or bonded together by an intermediate layer, and a method for manufacturing the same.

### 2. Description of the Related Art

Along with the rapid development in electronics industry and the progress of semiconductor processing technologies, semiconductor chips are integrated with an increasing number of electronic components to achieve improved electrical performance and additional functions. Accordingly, the semiconductor chips are provided with more input/output (I/O) connections. To manufacture semiconductor packages including semiconductor chips with an increased number of I/O connections, circuit layers of semiconductor substrates used for carrying the semiconductor chips may correspondingly increase in size. Thus, a thickness and a warpage of a semiconductor substrate may correspondingly increase, and a yield of the semiconductor substrate may decrease.

### SUMMARY

In some embodiments, a wiring structure includes: (a) an upper conductive structure including at least one upper dielectric layer and at least one upper circuit layer in contact with the upper dielectric layer; (b) a lower conductive structure including at least one lower dielectric layer and at least one lower circuit layer in contact with the lower dielectric layer; (c) an intermediate layer disposed between the upper conductive structure and the lower conductive structure and bonding the upper conductive structure and the lower conductive structure together; and (d) at least one lower through via extending through at least a portion of the lower conductive structure and the intermediate layer, and electrically connected to the upper circuit layer of the upper conductive structure.

In some embodiments, a wiring structure includes: (a) a low-density stacked structure including at least one dielectric layer and at least one low-density circuit layer in contact with the dielectric layer; (b) a high-density stacked structure disposed on the low-density stacked structure, wherein the high-density stacked structure includes at least one dielectric layer and at least a first high-density circuit layer in contact with the dielectric layer of the high-density stacked structure; and (c) at least one lower through via extending through at least a portion of the low-density stacked structure, and terminating at the first high-density circuit layer of the high-density stacked structure.

In some embodiments, a method for manufacturing a wiring structure includes: (a) providing a lower conductive structure including at least one dielectric layer and at least one circuit layer in contact with the dielectric layer; (b) providing an upper conductive structure including at least one dielectric layer and at least one circuit layer in contact with the dielectric layer of the upper conductive structure; (c) attaching the upper conductive structure to the lower conductive structure; and (d) electrically connecting the upper conductive structure and the lower conductive structure.

### BRIEF DESCRIPTION OF THE DRAWINGS

Aspects of some embodiments of the present disclosure are best understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of a wiring structure according to some embodiments of the present disclosure.

FIG. 2 illustrates a cross-sectional view of a wiring structure according to some embodiments of the present disclosure.

FIG. 2A illustrates a top view of an example of a fiducial mark of an upper conductive structure according to some embodiments of the present disclosure.

FIG. 2B illustrates a top view of an example of a fiducial mark of a lower conductive structure according to some embodiments of the present disclosure.

FIG. 2C illustrates a top view of a combination image of the fiducial mark of the upper conductive structure of FIG. 2A and the fiducial mark of the lower conductive structure of FIG. 2B.

FIG. 2D illustrates a top view of an example of a fiducial mark of an upper conductive structure according to some embodiments of the present disclosure.

FIG. 2E illustrates a top view of an example of a fiducial mark of a lower conductive structure according to some embodiments of the present disclosure.

FIG. 2F illustrates a top view of a combination image of the fiducial mark of the upper conductive structure of FIG. 2D and the fiducial mark of the lower conductive structure of FIG. 2E.

FIG. 2G illustrates a top view of an example of a fiducial mark of an upper conductive structure according to some embodiments of the present disclosure.

FIG. 2H illustrates a top view of an example of a fiducial mark of a lower conductive structure according to some embodiments of the present disclosure.

FIG. 2I illustrates a top view of a combination image of the fiducial mark of the upper conductive structure of FIG. 2G and the fiducial mark of the lower conductive structure of FIG. 2H.

FIG. 3 illustrates a cross-sectional view of a wiring structure according to some embodiments of the present disclosure.

FIG. 4 illustrates a cross-sectional view of a wiring structure according to some embodiments of the present disclosure.

FIG. 5 illustrates a cross-sectional view of a bonding of a package structure and a substrate.

FIG. 6 illustrates a cross-sectional view of a wiring structure according to some embodiments of the present disclosure.

FIG. 7 illustrates a cross-sectional view of a wiring structure according to some embodiments of the present disclosure.

FIG. 8 illustrates a cross-sectional view of a bonding of a package structure and a substrate.

FIG. 9 illustrates a cross-sectional view of a package structure according to some embodiments of the present disclosure.

FIG. 10 illustrates one or more stages of an example of a method for manufacturing a wiring structure according to some embodiments of the present disclosure.

FIG. 11 illustrates one or more stages of an example of a method for manufacturing a wiring structure according to some embodiments of the present disclosure.

FIG. 12 illustrates one or more stages of an example of a method for manufacturing a wiring structure according to some embodiments of the present disclosure.

FIG. 13 illustrates one or more stages of an example of a method for manufacturing a wiring structure according to some embodiments of the present disclosure.

FIG. 14 illustrates one or more stages of an example of a method for manufacturing a wiring structure according to some embodiments of the present disclosure.

FIG. 15 illustrates one or more stages of an example of a method for manufacturing wiring structure according to some embodiments of the present disclosure.

FIG. 16 illustrates one or more stages of an example of a method for manufacturing a wiring structure according to some embodiments of the present disclosure.

FIG. 17 illustrates one or more stages of an example of a method for manufacturing a wiring structure according to some embodiments of the present disclosure.

FIG. 18 illustrates one or more stages of an example of a method for manufacturing a wiring structure according to some embodiments of the present disclosure.

FIG. 19 illustrates one or more stages of an example of a method for manufacturing a wiring structure according to some embodiments of the present disclosure.

FIG. 20 illustrates one or more stages of an example of a method for manufacturing a wiring structure according to some embodiments of the present disclosure.

FIG. 21 illustrates one or more stages of an example of a method for manufacturing a wiring structure according to some embodiments of the present disclosure.

FIG. 22 illustrates one or more stages of an example of a method for manufacturing a wiring structure according to some embodiments of the present disclosure.

FIG. 23 illustrates one or more stages of an example of a method for manufacturing a wiring structure according to some embodiments of the present disclosure.

FIG. 24 illustrates one or more stages of an example of a method for manufacturing a wiring structure according to some embodiments of the present disclosure.

FIG. 25 illustrates one or more stages of an example of a method for manufacturing a wiring structure according to some embodiments of the present disclosure.

FIG. 26 illustrates one or more stages of an example of a method for manufacturing a wiring structure according to some embodiments of the present disclosure.

FIG. 27 illustrates one or more stages of an example of a method for manufacturing a wiring structure according to some embodiments of the present disclosure.

FIG. 28 illustrates one or more stages of an example of a method for manufacturing a wiring structure according to some embodiments of the present disclosure.

FIG. 29 illustrates one or more stages of an example of a method for manufacturing wiring structure according to some embodiments of the present disclosure.

FIG. 30 illustrates one or more stages of an example of a method for manufacturing a wiring structure according to some embodiments of the present disclosure.

FIG. 31 illustrates one or more stages of an example of a method for manufacturing a wiring structure according to some embodiments of the present disclosure.

FIG. 32 illustrates one or more stages of an example of a method for manufacturing a wiring structure according to some embodiments of the present disclosure.

FIG. 33 illustrates one or more stages of an example of a method for manufacturing a wiring structure according to some embodiments of the present disclosure.

FIG. 34 illustrates one or more stages of an example of a method for manufacturing a wiring structure according to some embodiments of the present disclosure.

FIG. 35 illustrates one or more stages of an example of a method for manufacturing a wiring structure according to some embodiments of the present disclosure.

FIG. 36 illustrates one or more stages of an example of a method for manufacturing a wiring structure according to some embodiments of the present disclosure.

FIG. 37 illustrates one or more stages of an example of a method for manufacturing a wiring structure according to some embodiments of the present disclosure.

FIG. 38 illustrates one or more stages of an example of a method for manufacturing a wiring structure according to some embodiments of the present disclosure.

FIG. 39 illustrates one or more stages of an example of a method for manufacturing a wiring structure according to some embodiments of the present disclosure.

FIG. 40 illustrates one or more stages of an example of a method for manufacturing wiring structure according to some embodiments of the present disclosure.

FIG. 41 illustrates one or more stages of an example of a method for manufacturing a wiring structure according to some embodiments of the present disclosure.

FIG. 42 illustrates one or more stages of an example of a method for manufacturing a wiring structure according to some embodiments of the present disclosure.

FIG. 43 illustrates one or more stages of an example of a method for manufacturing a wiring structure according to some embodiments of the present disclosure.

FIG. 44 illustrates one or more stages of an example of a method for manufacturing a wiring structure according to some embodiments of the present disclosure.

FIG. 45 illustrates one or more stages of an example of a method for manufacturing a wiring structure according to some embodiments of the present disclosure.

FIG. 46 illustrates one or more stages of an example of a method for manufacturing a wiring structure according to some embodiments of the present disclosure.

FIG. 47 illustrates one or more stages of an example of a method for manufacturing a wiring structure according to some embodiments of the present disclosure.

FIG. 48 illustrates one or more stages of an example of a method for manufacturing a wiring structure according to some embodiments of the present disclosure.

FIG. 49 illustrates one or more stages of an example of a method for manufacturing a wiring structure according to some embodiments of the present disclosure.

FIG. 50 illustrates one or more stages of an example of a method for manufacturing a wiring structure according to some embodiments of the present disclosure.

FIG. 51 illustrates one or more stages of an example of a method for manufacturing a wiring structure according to some embodiments of the present disclosure.

FIG. 52 illustrates one or more stages of an example of a method for manufacturing a wiring structure according to some embodiments of the present disclosure.

FIG. 53 illustrates one or more stages of an example of a method for manufacturing a wiring structure according to some embodiments of the present disclosure.

FIG. 54 illustrates one or more stages of an example of a method for manufacturing a wiring structure according to some embodiments of the present disclosure.

FIG. 55 illustrates one or more stages of an example of a method for manufacturing wiring structure according to some embodiments of the present disclosure.

FIG. 56 illustrates one or more stages of an example of a method for manufacturing a wiring structure according to some embodiments of the present disclosure.

FIG. 57 illustrates one or more stages of an example of a method for manufacturing a wiring structure according to some embodiments of the present disclosure.

FIG. 58 illustrates one or more stages of an example of a method for manufacturing a wiring structure according to some embodiments of the present disclosure.

FIG. 59 illustrates one or more stages of an example of a method for manufacturing a wiring structure according to some embodiments of the present disclosure.

FIG. 60 illustrates one or more stages of an example of a method for manufacturing a wiring structure according to some embodiments of the present disclosure.

FIG. 61 illustrates one or more stages of an example of a method for manufacturing a wiring structure according to some embodiments of the present disclosure.

FIG. 62 illustrates one or more stages of an example of a method for manufacturing a wiring structure according to some embodiments of the present disclosure.

FIG. 63 illustrates one or more stages of an example of a method for manufacturing a wiring structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

To meet the specification of increasing I/O counts, a number of dielectric layers of a substrate should increase. In some comparative embodiments, a manufacturing process of a core substrate may include the following stages. Firstly, a core with two copper foils disposed on two sides thereof is provided. Then, a plurality of dielectric layers and a plurality of circuit layers are formed or stacked on the two copper foils. One circuit layer may be embedded in one corresponding dielectric layer. Therefore, the core substrate may include a plurality of stacked dielectric layers and a plurality of circuit layers embedded in the dielectric layers on both sides of the core. Since a line width/line space (L/S) of the circuit layers of such core substrate may be greater than or equal to 10 micrometers (μm)/10 μm, the number of the dielectric layers of such core substrate is relatively large. Although the manufacturing cost of such core substrate is low, the manufacturing yield for the circuit layers and the dielectric layers of such core substrate is also low, and, thus, the yield of such core substrate is low. In addition, each dielectric layer is relatively thick, and, thus, such core substrate is relatively thick. In some comparative embodiments, if a package has 10000 I/O counts, such core substrate may include twelve layers of circuit layers and dielectric layers. The manufacturing yield for one layer (including one circuit layer and one dielectric layer) of such core substrate may be 90%. Thus, the yield of such core substrate may be (0.9)¹²=28.24%. In addition, warpage of the twelve layers of circuit layers and dielectric layers may be accumulated, and, thus, the top several layers may have severe warpage. As a result, the yield of such core substrate may be further reduced.

To address the above concerns, in some comparative embodiments, a coreless substrate is provided. The coreless substrate may include a plurality of dielectric layers and a plurality of fan-out circuit layers. In some embodiments, a manufacturing process of a coreless substrate may include the following stages. Firstly, a carrier is provided. Then, a plurality of dielectric layers and a plurality of fan-out circuit layers are formed or stacked on a surface of the carrier. One fan-out circuit layer may be embedded in one corresponding dielectric layer. Then, the carrier is removed. Therefore, the coreless substrate may include a plurality of stacked dielectric layers and a plurality of fan-out circuit layers embedded in the dielectric layers. Since a line width/line space (L/S) of the fan-out circuit layers of such coreless substrate may be less than or equal to 2 μm/2 μm, the number of the dielectric layers of such coreless substrate can be reduced. Further, the manufacturing yield for the fan-out circuit layers and the dielectric layers of such coreless substrate is high. For example, the manufacturing yield for one layer (including one fan-out circuit layer and one dielectric layer) of such coreless substrate may be 99%. However, the manufacturing cost of such coreless substrate is relatively high.

At least some embodiments of the present disclosure provide for a wiring structure which has an advantageous compromise of yield and manufacturing cost. In some embodiments, the wiring structure includes an upper conductive structure and a lower conductive structure bonded to the upper conductive structure through an intermediate layer. At least some embodiments of the present disclosure further provide for techniques for manufacturing the wiring structure.

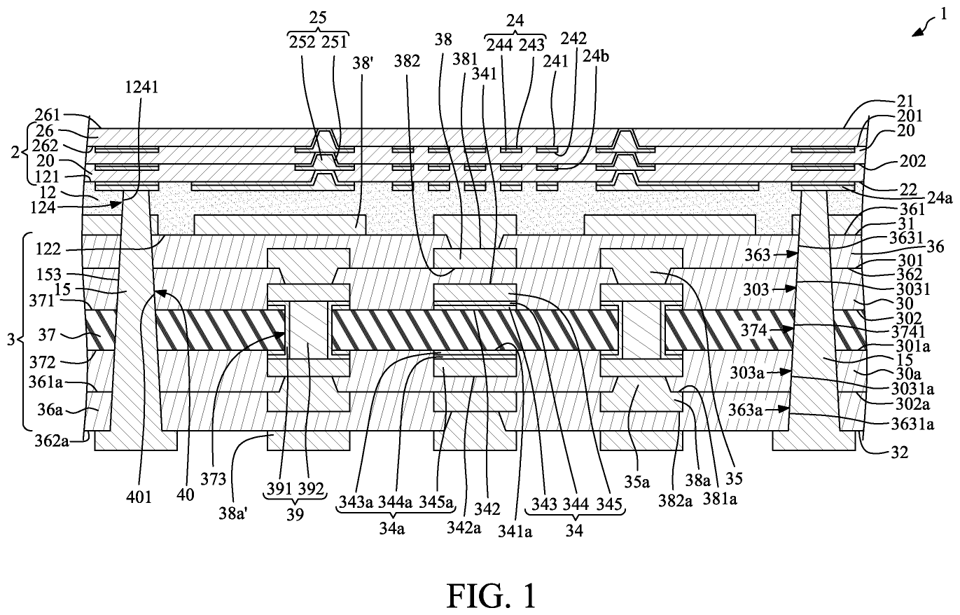

FIG. 1 illustrates a cross-sectional view of a wiring structure 1 according to some embodiments of the present disclosure. The wiring structure 1 includes an upper conductive structure 2, a lower conductive structure 3, an intermediate layer 12 and at least one lower through via 15.

The upper conductive structure 2 includes at least one dielectric layer (including, for example, two first dielectric layers 20 and a second dielectric layer 26) and at least one circuit layer (including, for example, three circuit layers 24 formed of a metal, a metal alloy, or other conductive material) in contact with the dielectric layer (e.g., the first dielectric layers 20 and the second dielectric layer 26). In some embodiments, the upper conductive structure 2 may be similar to a coreless substrate, and may be in a wafer type, a panel type or a strip type. The upper conductive structure 2 may be also referred to as “a stacked structure” or “a high-density conductive structure” or “a high-density stacked structure”. The circuit layer (including, for example, the three circuit layers 24) of the upper conductive structure 2 may be also referred to as “a high-density circuit layer”. In some embodiments, a density of a circuit line (including, for example, a trace or a pad) of the high-density circuit layer is greater than a density of a circuit line of a low-density circuit layer. That is, the count of the circuit line (including, for example, a trace or a pad) in a unit area of the high-density circuit layer is greater than the count of the circuit line in an equal unit area of the low-density circuit layer, such as about 1.2 times or greater, about 1.5 times or greater, or about 2 times or greater. Alternatively, or in combination, a line width/line space (L/S) of the high-density circuit layer is less than a L/S of the low-density circuit layer, such as about 90% or less, about 50% or less, or about 20% or less. Further, the conductive structure that includes the high-density circuit layer may be designated as the “high-density conductive structure”, and the conductive structure that includes the low-density circuit layer may be designated as a “low-density conductive structure”.

The upper conductive structure 2 has a top surface 21 and a bottom surface 22 opposite to the top surface 21. As shown in FIG. 1, the upper conductive structure 2 includes a plurality of dielectric layers (e.g., the two first dielectric layers 20 and the second dielectric layer 26), a plurality of circuit layers (e.g., the three circuit layers 24) and at least one inner via 25. The dielectric layers (e.g., the first dielectric layers 20 and the second dielectric layer 26) are stacked on one another. For example, the second dielectric layer 26 is disposed on the first dielectric layers 20, and, thus, the second dielectric layer 26 is the topmost dielectric layer. In some embodiments, a material of the dielectric layers (e.g., the first dielectric layers 20 and the second dielectric layer 26) is transparent, and can be seen through or detected by human eyes or machine. That is, a mark disposed adjacent to the bottom surface 22 of the upper conductive structure 2 can be recognized or detected from the top surface 21 of the upper conductive structure 2 by human eyes or machine. In some embodiments, a transparent material of the dielectric layers has a light transmission for a wavelength in the visible range (or other pertinent wavelength for detection of a mark) of at least about 60%, at least about 70%, or at least about 80%.

In addition, each of the first dielectric layers 20 has a top surface 201 and a bottom surface 202 opposite to the top surface 201. The second dielectric layer 26 has a top surface 261 and a bottom surface 262 opposite to the top surface 261. The bottom surface 262 of the second dielectric layer 26 is disposed on and contacts the top surface 201 of the adjacent first dielectric layer 20. Thus, the top surface 21 of the upper conductive structure 2 is the top surface 261 of the second dielectric layer 26, and the bottom surface 22 of the upper conductive structure 2 is the bottom surface 202 of the bottommost first dielectric layer 20.

The circuit layers 24 may be fan-out circuit layers or redistribution layers (RDLs), and an L/S of the circuit layers 24 may be less than or equal to about 2 μm/about 2 μm, or less than or equal to about 1.8 μm/about 1.8 μm. Each of the circuit layers 24 has a top surface 241 and a bottom surface 242 opposite to the top surface 241. In some embodiments, the circuit layer 24 is embedded in the corresponding first dielectric layer 20, and the top surface 241 of the circuit layer 24 may be substantially coplanar with the top surface 201 of the first dielectric layer 20. In some embodiments, each circuit layer 24 may include a seed layer 243 and a conductive metallic material 244 disposed on the seed layer 243. The circuit layers 24 may include a first circuit layer 24a (e.g., a first high-density circuit layer) and a second circuit layer 24b (e.g., a second high-density circuit layer). The first circuit layer 24a is the bottommost circuit layer, which is also referred to as “the first high-density circuit layer”. The second circuit layer 24b is disposed above the first circuit layer 24a. A thickness of the first circuit layer 24a is greater than a thickness of the second circuit layer 24b, such as about 1.1 times or greater, about 1.3 times or greater, or about 1.5 times or greater. For example, the thickness of the first circuit layer 24a may be about 4 μm, and the thickness of the second circuit layer 24b may be about 3 μm. This is because the first circuit layer 24a may be use to block a laser beam in a manufacturing process. As shown in FIG. 1, the bottommost circuit layer 24a (e.g., the first circuit layer 24a) is disposed on and protrudes from the bottom surface 22 of the upper conductive structure 2 (e.g., the bottom surface 202 of the bottommost first dielectric layer 20).

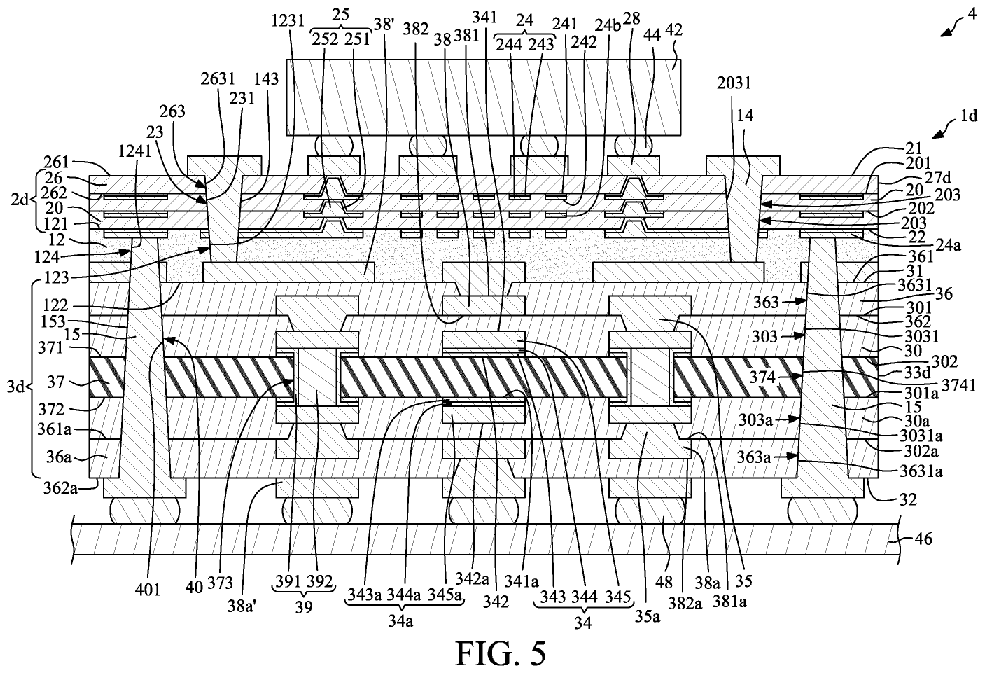

The upper conductive structure 2 includes a plurality of inner vias 25. Some of the inner vias 25 are disposed between two adjacent circuit layers 24 for electrically connecting the two circuit layers 24. Some of the inner vias 25 are exposed from the second dielectric layer 26 for electrically connecting a semiconductor chip 42 (FIG. 5). In some embodiments, each inner via 25 may include a seed layer 251 and a conductive metallic material 252 disposed on the seed layer 251. In some embodiments, each inner via 25 and the corresponding circuit layer 24 may be formed integrally as a monolithic or one-piece structure. Each inner via 25 tapers upwardly along a direction from the bottom surface 22 towards the top surface 21 of the upper conductive structure 2. That is, a size (e.g., a width) of a top portion of the inner via 25 is less than a size (e.g., a width) of a bottom portion of the inner via 25 that is closer towards the bottom surface 22. In some embodiments, a maximum width of the inner via 25 (e.g., at the bottom portion) may be less than or equal to about 25 μm, such as about 25 μm, about 20 μm, about 15 μm or about 10 μm.

The lower conductive structure 3 includes at least one dielectric layer (including, for example, one first upper dielectric layer 30, one second upper dielectric layer 36, one first lower dielectric layer 30a and one second lower dielectric layer 36a) and at least one circuit layer (including, for example, one first upper circuit layer 34, two second upper circuit layers 38, 38′, one first lower circuit layer 34a and two second lower circuit layers 38a, 38a′ formed of a metal, a metal alloy, or other conductive material) in contact with the dielectric layer (e.g., the first upper dielectric layer 30, the second upper dielectric layer 36, the first lower dielectric layer 30a and the second lower dielectric layer 36a). In some embodiments, the lower conductive structure 3 may be similar to a core substrate that further includes a core portion 37, and may be in a wafer type, a panel type or a strip type. The lower conductive structure 3 may be also referred to as “a stacked structure” or “a low-density conductive structure” or “a low-density stacked structure”. The circuit layer (including, for example, the first upper circuit layer 34, the two second upper circuit layers 38, 38′, the first lower circuit layer 34a and the two second lower circuit layers 38a, 38a′) of the lower conductive structure 3 may be also referred to as “a low-density circuit layer”. As shown in FIG. 1, the lower conductive structure 3 has a top surface 31 and a bottom surface 32 opposite to the top surface 31, and defines at least one through hole 40, each of which is a single, continuous through hole. The lower conductive structure 3 includes a plurality of dielectric layers (for example, the first upper dielectric layer 30, the second upper dielectric layer 36, the first lower dielectric layer 30a and the second lower dielectric layer 36a), a plurality of circuit layers (for example, the first upper circuit layer 34, the two second upper circuit layers 38, 38′, the first lower circuit layer 34a and the two second lower circuit layers 38a, 38a′) and at least one inner via (including, for example, a plurality of upper interconnection vias 35 and a plurality of lower interconnection vias 35a).

The core portion 37 has a top surface 371 and a bottom surface 372 opposite to the top surface 371, and defines a plurality of first through holes 373 and a plurality of second through holes 374 extending through the core portion 37. An interconnection via 39 is disposed or formed in each first through hole 373 for vertical connection. In some embodiments, each interconnection via 39 includes a base metallic layer 391 and an insulation material 392. The base metallic layer 391 is disposed or formed on a side wall of the first through hole 373, and defines a central through hole. The insulation material 392 fills the central through hole defined by the base metallic layer 391. In some embodiments, the interconnection via 39 may omit an insulation material, and may include a bulk metallic material that fills the first through hole 373. The second through hole 374 has an inner surface 3741.

The first upper dielectric layer 30 is disposed on the top surface 371 of the core portion 37. The first upper dielectric layer 30 has a top surface 301 and a bottom surface 302 opposite to the top surface 301, and defines a through hole 303 having an inner surface 3031. Thus, the bottom surface 302 of the first upper dielectric layer 30 contacts the top surface 371 of the core portion 37. The second upper dielectric layer 36 is stacked or disposed on the first upper dielectric layer 30. The second upper dielectric layer 36 has a top surface 361 and a bottom surface 362 opposite to the top surface 361, and defines a through hole 363 having an inner surface 3631. Thus, the bottom surface 362 of the second upper dielectric layer 36 contacts the top surface 301 of the first upper dielectric layer 30, and the second upper dielectric layer 36 is the topmost dielectric layer. In addition, the first lower dielectric layer 30a is disposed on the bottom surface 372 of the core portion 37. The first lower dielectric layer 30a has a top surface 301a and a bottom surface 302a opposite to the top surface 301a, and defines a through hole 303a having an inner surface 3031a. Thus, the top surface 301a of the first lower dielectric layer 30a contacts the bottom surface 372 of the core portion 37. The second lower dielectric layer 36a is stacked or disposed on the first lower dielectric layer 30a. The second lower dielectric layer 36a has a top surface 361a and a bottom surface 362a opposite to the top surface 361a, and defines a through hole 363a having an inner surface 3631a. Thus, the top surface 361a of the second lower dielectric layer 36a contacts the bottom surface 302a of the first lower dielectric layer 30a, and the second lower dielectric layer 36a is the bottommost dielectric layer. As shown in FIG. 1, the top surface 31 of the lower conductive structure 3 is the top surface 361 of the second upper dielectric layer 36, and the bottom surface 32 of the lower conductive structure 3 is the bottom surface 362a of the second lower dielectric layer 36a.

As shown in FIG. 1, each through hole 363 of the second upper dielectric layer 36 tapers upwardly along a direction from the bottom surface 32 towards the top surface 31 of the lower conductive structure 3; that is, a size of a top portion of the through hole 363 is less than a size of a bottom portion of the through hole 363. Each through hole 303 of the first upper dielectric layer 30 also tapers upwardly; that is, a size of a top portion of the through hole 303 is less than a size of a bottom portion of the through hole 303. The second through hole 374 of the core portion 37, the through hole 303a of the first lower dielectric layer 30a and the through hole 363a of the second lower dielectric layer 36a also taper upwardly. Further, the through hole 363 of the second upper dielectric layer 36, the through hole 303 of the first upper dielectric layer 30, the second through hole 374 of the core portion 37, the through hole 303a of the first lower dielectric layer 30a and the through hole 363a of the second lower dielectric layer 36a are aligned with each other and are in communication with each other. The bottom portion of the through hole 363 of the second upper dielectric layer 36 is disposed adjacent to or connected to the top portion of the through hole 303 of the first upper dielectric layer 30 under the second upper dielectric layer 36. The size of the bottom portion of the through hole 363 of the second upper dielectric layer 36 is substantially equal to the size of the top portion of the through hole 303 of the first upper dielectric layer 30. Thus, the inner surface 3631 of the through hole 363 of the second upper dielectric layer 36 is coplanar with or aligned with the inner surface 3031 of the through hole 303 of the first upper dielectric layer 30. Similarly, the bottom portion of the through hole 303 of the first upper dielectric layer 30 is disposed adjacent to or connected to the top portion of the second through hole 374 of the core portion 37. The size of the bottom portion of the through hole 303 of the first upper dielectric layer 30 is substantially equal to the size of the top portion of the second through hole 374 of the core portion 37. Thus, the inner surface 3031 of the through hole 303 of the first upper dielectric layer 30 is coplanar with or aligned with the inner surface 3741 of the second through hole 374 of the core portion 37. Similarly, the inner surface 3741 of the second through hole 374 of the core portion 37, the inner surface 3031a of the through hole 303a of the first lower dielectric layer 30a and the inner surface 3631a of the through hole 363a of the second lower dielectric layer 36a are coplanar with or aligned with each other.

It is noted that the above-mentioned “coplanar” surfaces need not be flat. In some embodiments, the inner surface 3631 of the through hole 363, the inner surface 3031 of the through hole 303, the inner surface 3741 of the second through hole 374, the inner surface 3031a of the through hole 303a and the inner surface 3631a of the through hole 363a may be curved surfaces, and are portions of an inner surface 401 of the single, continuous through hole 40 for accommodating the lower through via 15. The through hole 363, the through hole 303, the second through hole 374, the through hole 303a and the through hole 363a are collectively configured to form or define a portion of the single through hole 40. As shown in FIG. 1, cross-sectional views of one side of the inner surface 3631 of the through hole 363, the inner surface 3031 of the through hole 303, the inner surface 3741 of the second through hole 374, the inner surface 3031a of the through hole 303a and the inner surface 3631a of the through hole 363a are segments of a substantially straight line. That is, cross-sectional views of one side of the inner surface 3631 of the through hole 363, the inner surface 3031 of the through hole 303, the inner surface 3741 of the second through hole 374, the inner surface 3031a of the through hole 303a and the inner surface 3631a of the through hole 363a may extend along the same substantially straight line. The single through hole 40 extends through the lower conductive structure 3; that is, the single through hole 40 extends from the bottom surface 32 of the lower conductive structure 3 to the top surface 31 of the lower conductive structure 3. The single through hole 40 tapers upwardly.

A thickness of each of the dielectric layers (e.g., the first dielectric layers 20 and the second dielectric layer 26) of the upper conductive structure 2 is less than or equal to about 40%, less than or equal to about 35%, or less than or equal to about 30% of a thickness of each of the dielectric layers (e.g., the first upper dielectric layer 30, the second upper dielectric layer 36, the first lower dielectric layer 30a and the second lower dielectric layer 36a) of the lower conductive structure 3. For example, a thickness of each of the dielectric layers (e.g., the first dielectric layers 20 and the second dielectric layer 26) of the upper conductive structure 2 may be less than or equal to about 7 μm, and a thickness of each of the dielectric layers (e.g., the first upper dielectric layer 30, the second upper dielectric layer 36, the first lower dielectric layer 30a and the second lower dielectric layer 36a) of the lower conductive structure 3 may be about 40 μm.

An L/S of the first upper circuit layer 34 may be greater than or equal to about 10 μm/about 10 μm. Thus, the L/S of the first upper circuit layer 34 may be greater than or equal to about five times the L/S of the circuit layers 24 of the upper conductive structure 2. The first upper circuit layer 34 has a top surface 341 and a bottom surface 342 opposite to the top surface 341. In some embodiments, the first upper circuit layer 34 is formed or disposed on the top surface 371 of the core portion 37, and covered by the first upper dielectric layer 30. The bottom surface 342 of the first upper circuit layer 34 contacts the top surface 371 of the core portion 37. In some embodiments, the first upper circuit layer 34 may include a first metallic layer 343, a second metallic layer 344 and a third metallic layer 345. The first metallic layer 343 is disposed on the top surface 371 of the core portion 37, and may be made formed from a copper foil (e.g., may constitute a portion of the copper foil). The second metallic layer 344 is disposed on the first metallic layer 343, and may be a plated copper layer. The third metallic layer 345 is disposed on the second metallic layer 344, and may be another plated copper layer. In some embodiments, the third metallic layer 345 may be omitted.

An L/S of the second upper circuit layer 38 may be greater than or equal to about 10 μm/about 10 μm. Thus, the L/S of the second upper circuit layer 38 may be substantially equal to the L/S of the first upper circuit layer 34, and may be greater than or equal to about five times the L/S of the circuit layers 24 of the upper conductive structure 2. The second upper circuit layer 38 has a top surface 381 and a bottom surface 382 opposite to the top surface 381. In some embodiments, the second upper circuit layer 38 is formed or disposed on the top surface 301 of the first upper dielectric layer 30, and covered by the second upper dielectric layer 36. The bottom surface 382 of the second upper circuit layer 38 contacts the top surface 301 of the first upper dielectric layer 30. In some embodiments, the second upper circuit layer 38 is electrically connected to the first upper circuit layer 34 through the upper interconnection vias 35. That is, the upper interconnection vias 35 are disposed between the second upper circuit layer 38 and the first upper circuit layer 34 for electrically connecting the second upper circuit layer 38 and the first upper circuit layer 34. In some embodiments, the second upper circuit layer 38 and the upper interconnection vias 35 are formed integrally as a monolithic or one-piece structure. Each upper interconnection via 35 tapers downwardly along a direction from the top surface 31 towards the bottom surface 32 of the lower conductive structure 3.

In addition, in some embodiments, the second upper circuit layer 38′ is disposed on and protrudes from the top surface 361 of the second upper dielectric layer 36. In some embodiments, the second upper circuit layer 38 is electrically connected to the second upper circuit layer 38′ through the upper interconnection vias 35. That is, the upper interconnection vias 35 are disposed between the second upper circuit layers 38, 38′ for electrically connecting the second upper circuit layers 38, 38′. In some embodiments, the second upper circuit layer 38′ and the upper interconnection vias 35 are formed integrally as a monolithic or one-piece structure. In some embodiments, the second upper circuit layer 38′ is the topmost circuit layer of the lower conductive structure 3.

An L/S of the first lower circuit layer 34a may be greater than or equal to about 10 μm/about 10 μm. Thus, the L/S of the first lower circuit layer 34a may be greater than or equal to about five times the L/S of the circuit layers 24 of the upper conductive structure 2. The first lower circuit layer 34a has a top surface 341a and a bottom surface 342a opposite to the top surface 341a. In some embodiments, the first lower circuit layer 34a is formed or disposed on the bottom surface 372 of the core portion 37, and covered by the first lower dielectric layer 30a. The top surface 341a of the first lower circuit layer 34a contacts the bottom surface 372 of the core portion 37. In some embodiments, the first lower circuit layer 34a may include a first metallic layer 343a, a second metallic layer 344a and a third metallic layer 345a. The first metallic layer 343a is disposed on the bottom surface 372 of the core portion 37, and may be formed from a copper foil. The second metallic layer 344a is disposed on the first metallic layer 343a, and may be a plated copper layer. The third metallic layer 345a is disposed on the second metallic layer 344a, and may be another plated copper layer. In some embodiments, the third metallic layer 345a may be omitted.

An L/S of the second lower circuit layer 38a may be greater than or equal to about 10 μm/about 10 μm. Thus, the L/S of the second lower circuit layer 38a may be substantially equal to the L/S of the first upper circuit layer 34, and may be greater than or equal to about five times the L/S of the circuit layers 24 of the upper conductive structure 2. The second lower circuit layer 38a has a top surface 381a and a bottom surface 382a opposite to the top surface 381a. In some embodiments, the second lower circuit layer 38a is formed or disposed on the bottom surface 302a of the first lower dielectric layer 30a, and covered by the second lower dielectric layer 36a. The top surface 381a of the second lower circuit layer 38a contacts the bottom surface 302a of the first lower dielectric layer 30a. In some embodiments, the second lower circuit layer 38a is electrically connected to the first lower circuit layer 34a through the lower interconnection vias 35a. That is, the lower interconnection vias 35a are disposed between the second lower circuit layer 38a and the first lower circuit layer 34a for electrically connecting the second lower circuit layer 38a and the first lower circuit layer 34a. In some embodiments, the second lower circuit layer 38a and the lower interconnection vias 35a are formed integrally as a monolithic or one-piece structure. The lower interconnection via 35a tapers upwardly along a direction from the bottom surface 32 towards the top surface 31 of the lower conductive structure 3.

In addition, in some embodiments, the second lower circuit layer 38a′ is disposed on and protrudes from the bottom surface 362a of the second lower dielectric layer 36a. In some embodiments, the second lower circuit layer 38a′ is electrically connected to the second lower circuit layer 38a through the lower interconnection vias 35a. That is, the lower interconnection vias 35a are disposed between the second lower circuit layers 38a, 38a′ for electrically connecting the second lower circuit layers 38a, 38a′. In some embodiments, the second lower circuit layer 38a′ and the lower interconnection vias 35a are formed integrally as a monolithic or one-piece structure. In some embodiments, the second lower circuit layer 38a′ is the bottommost low-density circuit layer of the lower conductive structure 3.

In some embodiments, each interconnection via 39 electrically connects the first upper circuit layer 34 and the first lower circuit layer 34a. The base metallic layer 391 of the interconnection via 39, the second metallic layer 344 of the first upper circuit layer 34 and the second metal layer 344a the first lower circuit layer 34a may be formed integrally and concurrently as a monolithic or one-piece structure.

The intermediate layer 12 is interposed or disposed between the upper conductive structure 2 and the lower conductive structure 3 to bond the upper conductive structure 2 and the lower conductive structure 3 together. That is, the intermediate layer 12 adheres to the bottom surface 22 of the upper conductive structure 2 and the top surface 31 of the lower conductive structure 3. In some embodiments, the intermediate layer 12 may be an adhesion layer that is cured from an adhesive material (e.g., includes a cured adhesive material such as an adhesive polymeric material). The intermediate layer 12 has a top surface 121 and a bottom surface 122 opposite to the top surface 121, and defines at least one first through hole 124 having an inner surface 1241. The top surface 121 of the intermediate layer 12 contacts the bottom surface 22 of the upper conductive structure 2 (that is, the bottom surface 22 of the upper conductive structure 2 is attached to the top surface 121 of the intermediate layer 12), and the bottom surface 122 of the intermediate layer 12 contacts the top surface 31 of the lower conductive structure 3. Thus, the bottommost circuit layer 24a (e.g., the first circuit layer 24a) of the upper conductive structure 2 and the topmost circuit layer 38′ (e.g., the second upper circuit layer 38′) of the lower conductive structure 3 are embedded in the intermediate layer 12. In some embodiments, a bonding force between two adjacent dielectric layers (e.g., two adjacent first dielectric layers 20) of the upper conductive structure 2 is greater than a bonding force between a dielectric layer (e.g., the bottommost first dielectric layer 20) of the upper conductive structure 2 and the intermediate layer 12. A surface roughness of a boundary between two adjacent dielectric layers (e.g., two adjacent first dielectric layers 20) of the upper conductive structure 2 is greater than a surface roughness of a boundary between a dielectric layer (e.g., the bottommost first dielectric layer 20) of the upper conductive structure 2 and the intermediate layer 12, such as about 1.1 times or greater, about 1.3 times or greater, or about 1.5 times or greater in terms of root mean squared surface roughness.

In some embodiments, a material of the intermediate layer 12 is transparent, and can be seen through by human eyes or machine. That is, a mark disposed adjacent to the top surface 31 of the lower conductive structure 3 can be recognized or detected from the top surface 21 of the upper conductive structure 2 by human eyes or machine.

The first through hole 124 extends through the intermediate layer 12. In some embodiments, the first through hole 124 of the intermediate layer 12 may extend through the topmost circuit layer (e.g., the second upper circuit layer 38′) of the lower conductive structure 3 and terminate at or on the bottommost circuit layer 24a (e.g., the first circuit layer 24a) of the upper conductive structure 2. That is, the first through hole 124 of the intermediate layer 12 may not extend through the bottommost circuit layer 24a (e.g., the first circuit layer 24a) of the upper conductive structure 2. The first through hole 124 of the intermediate layer 12 may expose a portion of the bottommost circuit layer 24a (e.g., the first circuit layer 24a) of the upper conductive structure 2.

As shown in FIG. 1, the first through hole 124 of the intermediate layer 12 tapers upwardly along a direction from the bottom surface 122 towards the top surface 121 of the intermediate layer 12; that is, a size of a top portion of the first through hole 124 is smaller than a size of a bottom portion of the first through hole 124. Further, the first through hole 124 of the intermediate layer 12 is aligned with and in communication with the through hole 363 of the second upper dielectric layer 36, the through hole 303 of the first upper dielectric layer 30, the second through hole 374 of the core portion 37, the through hole 303a of the first lower dielectric layer 30a and the through hole 363a of the second lower dielectric layer 36a. The bottom portion of the first through hole 124 of the intermediate layer 12 is disposed adjacent to or connected to the top portion of the through hole 363 of the second upper dielectric layer 36. The size of the bottom portion of the first through hole 124 of the intermediate layer 12 is substantially equal to the size of the top portion of the through hole 363 of the second upper dielectric layer 36. Thus, the inner surface 1241 of the first through hole 124 of the intermediate layer 12 is coplanar or aligned with the inner surface 3631 of the through hole 363, the inner surface 3031 of the through hole 303, the inner surface 3741 of the second through hole 374, the inner surface 3031a of the through hole 303a and the inner surface 3631a of the through hole 363. In some embodiments, inner surface 1241 of the first through hole 124 of the intermediate layer 12 may be a curved surface, and is a portion of an inner surface 401 of the single, continuous through hole 40 for accommodating the lower through via 15. The first through hole 124 of the intermediate layer 12, the through hole 363 of the second upper dielectric layer 36, the through hole 303 of the first upper dielectric layer 30, the second through hole 374 of the core portion 37, the through hole 303a of the first lower dielectric layer 30a and the through hole 363a of the second lower dielectric layer 36a are collectively configured to form or define the single through hole 40. Thus, the single through hole 40 includes the first through hole 124 of the intermediate layer 12, the through hole 363 of the second upper dielectric layer 36, the through hole 303 of the first upper dielectric layer 30, the second through hole 374 of the core portion 37, the through hole 303a of the first lower dielectric layer 30a and the through hole 363a of the second lower dielectric layer 36a.

As shown in FIG. 1, cross-sectional views of one side of the inner surface 1241 of the first through hole 124 of the intermediate layer 12, the inner surface 3631 of the through hole 363, the inner surface 3031 of the through hole 303, the inner surface 3741 of the second through hole 374, the inner surface 3031a of the through hole 303a and the inner surface 3631a of the through hole 363a are segments of a substantially straight line. That is, cross-sectional views of one side of the inner surface 1241 of the first through hole 124 of the intermediate layer 12, the inner surface 3631 of the through hole 363, the inner surface 3031 of the through hole 303, the inner surface 3741 of the second through hole 374, the inner surface 3031a of the through hole 303a and the inner surface 3631a of the through hole 363a may extend along the same substantially straight line. The single through hole 40 extends through the lower conductive structure 3 and the intermediate layer 12; that is, the single through hole 40 extends from the bottom surface 32 of the lower conductive structure 3 to the top portion of the intermediate layer 12 to expose a portion of the bottommost circuit layer 24a (e.g., the bottom surface of the first circuit layer 24a) of the upper conductive structure 2. The single through hole 40 tapers upwardly. A maximum width (e.g., at the bottom portion) of the single through hole 40 may be about 25 μm to about 60 μm.

Each lower through via 15 is formed or disposed in the corresponding single through hole 40, and is formed of a metal, a metal alloy, or other conductive material. Thus, the lower through via 15 extends through at least a portion of the lower conductive structure 3 and the intermediate layer 12, and is electrically connected to a circuit layer (e.g., the bottom surface of the first circuit layer 24a) of the upper conductive structure 2. As shown in FIG. 1, the lower through via 15 extends through and contacts the topmost circuit layer (e.g., the second upper circuit layer 38′) of the lower conductive structure 3, and terminates at or on, and contacts a portion of the bottommost circuit layer (e.g., the bottom surface of the first circuit layer 24a) of the upper conductive structure 2. The lower through via 15 extends from the bottom surface 32 of the lower conductive structure 3 to the top portion of the intermediate layer 12. Thus, the lower through via 15 extends to contact a portion of the upper conductive structure 2, and the lower through via 15 does not extend through the upper conductive structure 2. In some embodiments, a low-density circuit layer (e.g., the second upper circuit layer 38′) of the low-density conductive structure (e.g., the lower conductive structure 3) is electrically connected to a high-density circuit layer (e.g., the first circuit layer 24a) of the high-density conductive structure (e.g., the upper conductive structure 2) solely by the lower through via 15 extending through the low-density circuit layer (e.g., the second upper circuit layer 38′) of the low-density conductive structure (e.g., the lower conductive structure 3). A length (along a longitudinal axis) of the lower through via 15 is greater than a thickness of the low-density conductive structure (e.g., the lower conductive structure 3). Further, the lower through via 15 tapers upwardly; that is, a size of a top portion of the lower through via 15 is smaller than a size of a bottom portion of the lower through via 15. Thus, a tapering direction of the inner vias 25 of the upper conductive structure 2 is the same as a tapering direction of the lower through via 15. In some embodiments, the lower through via 15 is a monolithic structure or a one-piece structure having a homogeneous material composition, and a peripheral surface 153 of the lower through via 15 is a substantially continuous surface without boundaries. The lower through via 15 and the second lower circuit layer 38a′ may be formed integrally.

As shown in the embodiment illustrated in FIG. 1, the wiring structure 1 is a combination of the upper conductive structure 2 and the lower conductive structure 3, in which the circuit layers 24 of the upper conductive structure 2 has fine pitch, high yield and low thickness; and the circuit layers (for example, the first upper circuit layer 34, the second upper circuit layers 38, 38′, the first lower circuit layer 34a and the second lower circuit layers 38a, 38a′) of the lower conductive structure 3 have low manufacturing cost. Thus, the wiring structure 1 has an advantageous compromise of yield and manufacturing cost, and the wiring structure 1 has a relatively low thickness. In some embodiments, if a package has 10000 I/O counts, the wiring structure 1 includes three layers of the circuit layers 24 of the upper conductive structure 2 and six layers of the circuit layers (for example, the first upper circuit layer 34, the second upper circuit layers 38, 38′, the first lower circuit layer 34a and the second lower circuit layers 38a, 38a′) of the lower conductive structure 3. The manufacturing yield for one layer of the circuit layers 24 of the upper conductive structure 2 may be 99%, and the manufacturing yield for one layer of the circuit layers (for example, the first upper circuit layer 34, the second upper circuit layers 38, 38′, the first lower circuit layer 34a and the second lower circuit layers 38a, 38a′) of the lower conductive structure 3 may be 90%. Thus, the yield of the wiring structure 1 may be improved. In addition, the warpage of the upper conductive structure 2 and the warpage of the lower conductive structure 3 are separated and will not influence each other. In some embodiments, a warpage shape of the upper conductive structure 2 may be different from a warpage shape of the lower conductive structure 3. For example, the warpage shape of the upper conductive structure 2 may be a convex shape, and the warpage shape of the lower conductive structure 3 may be a concave shape. In some embodiments, the warpage shape of the upper conductive structure 2 may be the same as the warpage shape of the lower conductive structure 3; however, the warpage of the lower conductive structure 3 will not be accumulated onto the warpage of the upper conductive structure 2. Thus, the yield of the wiring structure 1 may be further improved.

In addition, during a manufacturing process, the lower conductive structure 3 and the upper conductive structure 2 may be tested individually before being bonded together. Therefore, known good lower conductive structure 3 and known good upper conductive structure 2 may be selectively bonded together. Bad (or unqualified) lower conductive structure 3 and bad (or unqualified) upper conductive structure 2 may be discarded. As a result, the yield of the wiring structure 1 may be further improved.

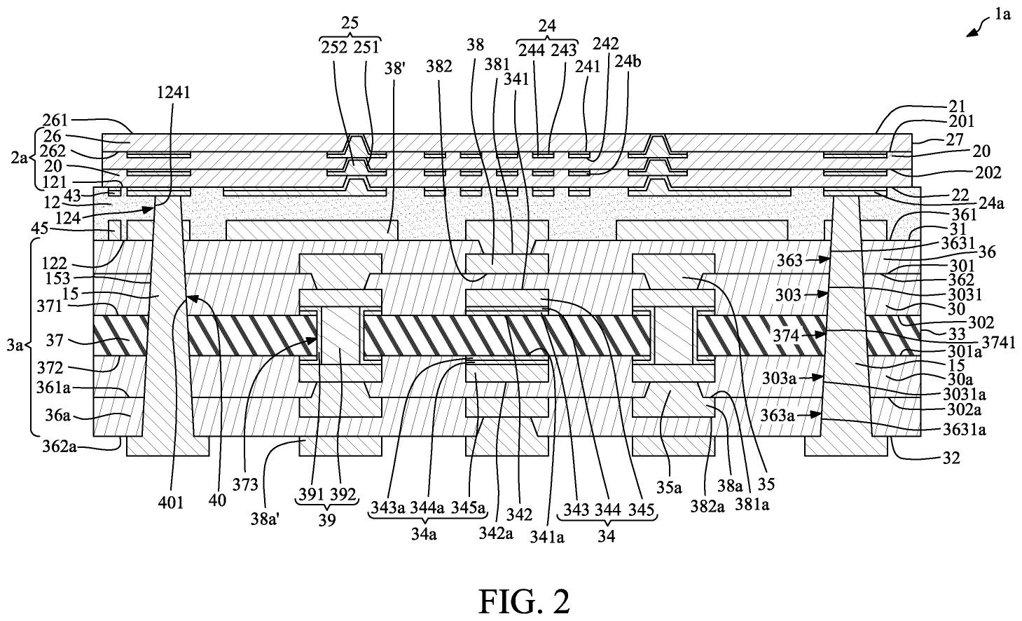

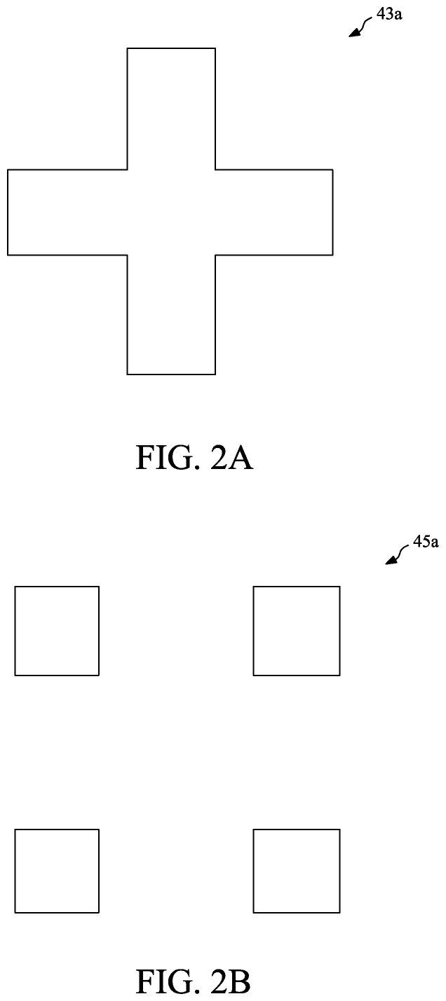

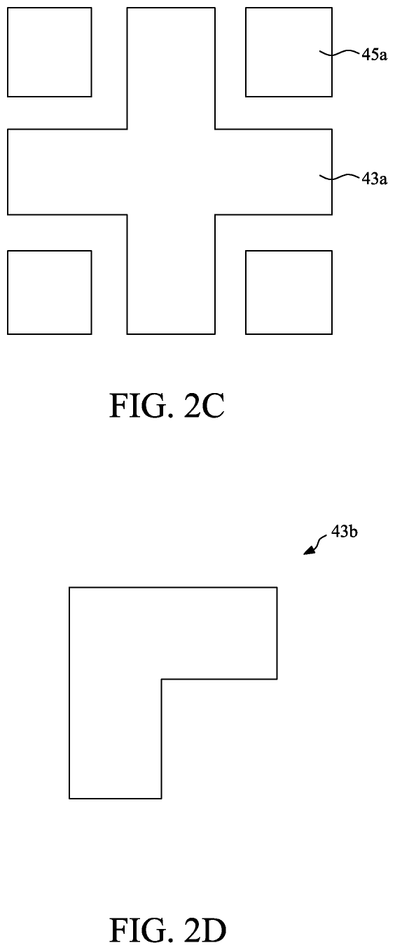

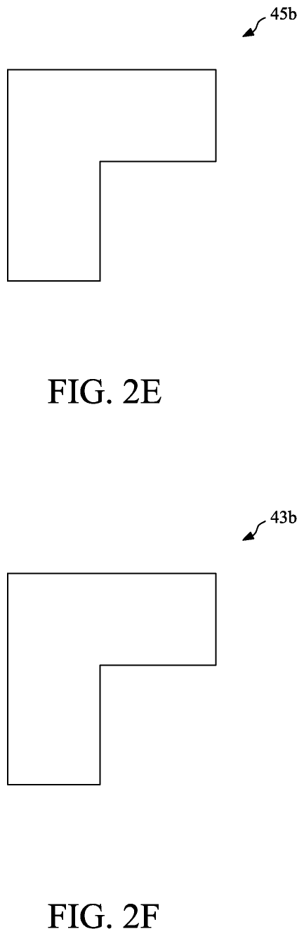

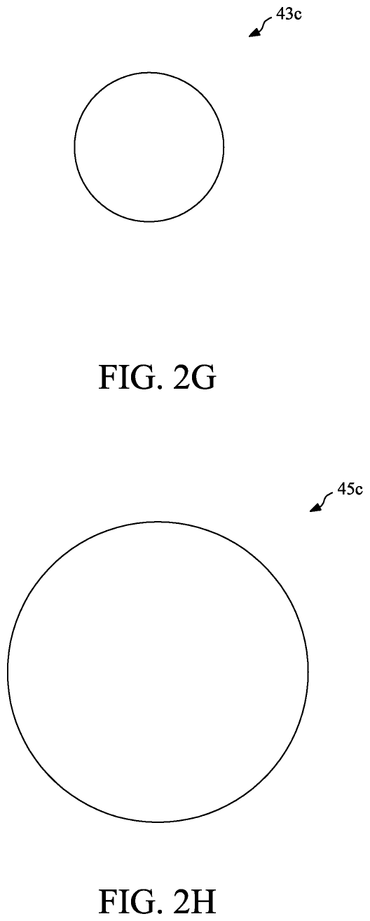

FIG. 2 illustrates a cross-sectional view of a wiring structure la according to some embodiments of the present disclosure. The wiring structure la is similar to the wiring structure 1 shown in FIG. 1, except for structures of an upper conductive structure 2a and a lower conductive structure 3a. As shown in FIG. 2, the upper conductive structure 2a and the lower conductive structure 3a are both strip structures. Thus, the wiring structure 1a is a strip structure. In some embodiments, the lower conductive structure 3a may be a panel structure that carries a plurality of strip upper conductive structures 2a. Thus, the wiring structure 1a is a panel structure. A length (e.g., about 240 mm) of the upper conductive structure 2a is greater than a width (e.g., about 95 mm) of the upper conductive structure 2a from a top view. Further, a length of the lower conductive structure 3a is greater than a width of the lower conductive structure 3a from a top view. In addition, a lateral peripheral surface 27 of the upper conductive structure 2a is not coplanar with (e.g., is inwardly recessed from or otherwise displaced from) a lateral peripheral surface 33 of the lower conductive structure 3a. In some embodiments, during a manufacturing process, the lower conductive structure 3a and the upper conductive structure 2a may be both known good strip structures. Alternatively, the upper conductive structure 2a may be a known good strip structure, and the lower conductive structure 3a may be a known good panel structure. As a result, the yield of the wiring structure la may be further improved.

As shown in FIG. 2, the upper conductive structure 2a includes at least one fiducial mark 43 at a corner thereof, and the lower conductive structure 3a has at least one fiducial mark 45 at a corner thereof. The fiducial mark 43 of the upper conductive structure 2a is aligned with a fiducial mark 45 of the lower conductive structure 3a during a manufacturing process, so that the relative position of the upper conductive structure 2a and the lower conductive structure 3a is secured. In some embodiments, the fiducial mark 43 of the upper conductive structure 2a is disposed on and protrudes from the bottom surface 22 of the upper conductive structure 2a (e.g., the bottom surface 202 of the bottommost first dielectric layer 20). The fiducial mark 43 and the bottommost circuit layer 24a (e.g., the first circuit layer 24a) may be at, or part of, the same layer, and may be formed concurrently. Further, the fiducial mark 45 of the lower conductive structure 3a is disposed on and protrudes from the top surface 31 of the lower conductive structure 3a (e.g., the top surface 361 of the second upper dielectric layer 36). The fiducial mark 45 and the second upper circuit layer 38′ may be at, or part of, the same layer, and may be formed concurrently.

FIG. 2A illustrates a top view of an example of a fiducial mark 43a of the upper conductive structure 2a according to some embodiments of the present disclosure. The fiducial mark 43a of the upper conductive structure 2a has a continuous cross shape.

FIG. 2B illustrates a top view of an example of a fiducial mark 45a of the lower conductive structure 3a according to some embodiments of the present disclosure. The fiducial mark 45a of the lower conductive structure 3a includes four square-shaped segments spaced apart at four corners.

FIG. 2C illustrates a top view of a combination image of the fiducial mark 43a of the upper conductive structure 2a of FIG. 2A and the fiducial mark 45a of the lower conductive structure 3a of FIG. 2B. When the upper conductive structure 2a is aligned with the lower conductive structure 3a precisely, the combination image shows the complete fiducial mark 43a and the complete fiducial mark 45a, as shown in FIG. 2C. That is, the fiducial mark 43a does not cover or overlap the fiducial mark 45a from the top view.

FIG. 2D illustrates a top view of an example of a fiducial mark 43b of the upper conductive structure 2a according to some embodiments of the present disclosure. The fiducial mark 43b of the upper conductive structure 2a has a continuous reversed “L” shape.

FIG. 2E illustrates a top view of an example of a fiducial mark 45b of the lower conductive structure 3a according to some embodiments of the present disclosure. The fiducial mark 45b of the lower conductive structure 3a has a continuous reversed “L” shape which is substantially the same as the fiducial mark 43b of the upper conductive structure 2a.

FIG. 2F illustrates a top view of a combination image of the fiducial mark 43b of the upper conductive structure 2a of FIG. 2D and the fiducial mark 45b of the lower conductive structure 3a of FIG. 2E. When the upper conductive structure 2a is aligned with the lower conductive structure 3a precisely, the combination image shows solely the fiducial mark 43b of the upper conductive structure 2a, as shown in FIG. 2F. That is, the fiducial mark 43b completely covers or overlaps the fiducial mark 45b from the top view.

FIG. 2G illustrates a top view of an example of a fiducial mark 43c of the upper conductive structure 2a according to some embodiments of the present disclosure. The fiducial mark 43c of the upper conductive structure 2a has a continuous circular shape.

FIG. 2H illustrates a top view of an example of a fiducial mark 45c of the lower conductive structure 3a according to some embodiments of the present disclosure. The fiducial mark 45c of the lower conductive structure 3a has a continuous circular shape which is larger than the fiducial mark 43c of the upper conductive structure 2a.

FIG. 2I illustrates a top view of a combination image of the fiducial mark 43c of the upper conductive structure 2a of FIG. 2G and the fiducial mark 45c of the lower conductive structure 3a of FIG. 2H. When the upper conductive structure 2a is aligned with the lower conductive structure 3a precisely, the combination image shows two concentric circles, as shown in FIG. 2I. That is, the fiducial mark 43c is disposed at the center of the fiducial mark 45c.

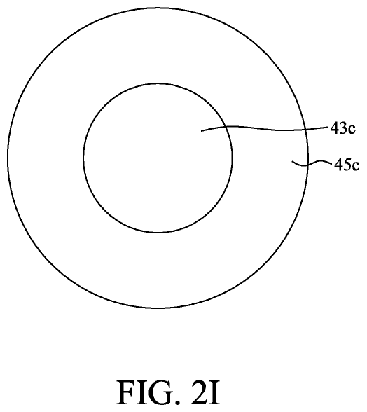

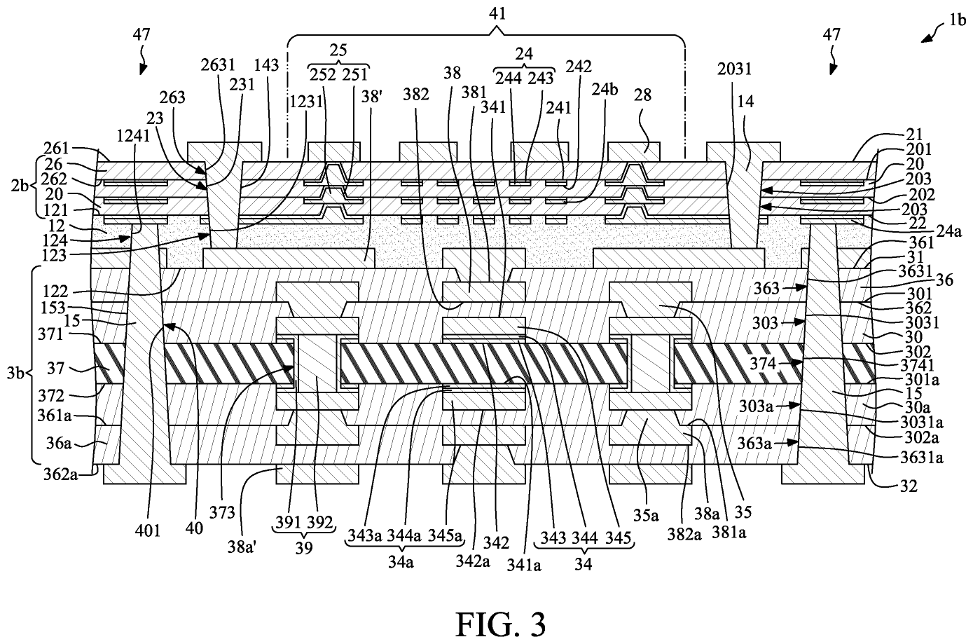

FIG. 3 illustrates a cross-sectional view of a wiring structure 1b according to some embodiments of the present disclosure. The wiring structure 1b is similar to the wiring structure 1 shown in FIG. 1, except that the wiring structure 1b further includes at least one upper through via 14 and an outer circuit layer 28. An upper conductive structure 2b defines at least one single, continuous through hole 23 for accommodating each upper through via 14. Each of the first dielectric layers 20 of the upper conductive structure 2b defines a through hole 203 having an inner surface 2031. The second dielectric layer 26 of the upper conductive structure 2b defines a through hole 263 having an inner surface 2631. As shown in FIG. 3, each of the through holes 203 of the first dielectric layers 20 tapers downwardly along a direction from the top surface 21 towards the bottom surface 22 of the upper conductive structure 2b; that is, a size of a top portion of the through hole 203 is greater than a size of a bottom portion of the through hole 203. The through hole 263 of the second dielectric layer 26 also tapers downwardly; that is, a size of a top portion of the through hole 263 is greater than a size of a bottom portion of the through hole 263. Further, the through hole 263 of the second dielectric layer 26 is aligned with and in communication with the through holes 203 of the first dielectric layers 20. The bottom portion of the through hole 263 of the second dielectric layer 26 is disposed adjacent to or connected to the top portion of the through hole 203 of the first dielectric layer 20 under the second dielectric layer 26. The size of the bottom portion of the through hole 263 of the second dielectric layer 26 is substantially equal to the size of the top portion of the through hole 203 of the first dielectric layer 20 under the second dielectric layer 26. Thus, the inner surface 2631 of the through hole 263 of the second dielectric layer 26 is coplanar with or aligned with the inner surfaces 2031 of the through holes 203 of the first dielectric layers 20. It is noted that the above-mentioned “coplanar” surfaces need not be flat. In some embodiments, the inner surface 2631 of the through hole 263 of the second dielectric layer 26 and the inner surfaces 2031 of the through holes 203 of the first dielectric layers 20 may be curved surfaces, and are portions of an inner surface 231 of the single, continuous through hole 23 for accommodating the upper through via 14. The through hole 263 of the second dielectric layer 26 and the through holes 203 of the first dielectric layers 20 are collectively configured to form or define a portion of the single through hole 23. As shown in FIG. 3, cross-sectional views of one side of the inner surface 2631 of the through hole 263 of the second dielectric layer 26 and the inner surfaces 2031 of the through holes 203 of the first dielectric layers 20 are segments of a substantially straight line. That is, cross-sectional views of one side of the inner surface 2631 of the through hole 263 of the second dielectric layer 26 and the inner surfaces 2031 of the through holes 203 of the first dielectric layers 20 may extend along the same substantially straight line. The single through hole 23 extends through the upper conductive structure 2b; that is, the single through hole 23 extends from the top surface 21 of the upper conductive structure 2b to the bottom surface 22 of the upper conductive structure 2b. The single through hole 23 tapers downwardly.

In addition, the outer circuit layer 28 (e.g., a top low-density circuit layer) is disposed on and protrudes from the top surface 21 of the upper conductive structure 2b (e.g., the top surface 261 of the second dielectric layer 26). An L/S of the outer circuit layer 28 may be greater than or equal to the L/S of the circuit layers 24. In some embodiments, an L/S of the outer circuit layer 28 may be substantially equal to the L/S of the second lower circuit layer 38a′. As illustrated in the embodiment of FIG. 3, a horizontally connecting or extending circuit layer is omitted in the second dielectric layer 26.

The intermediate layer 12 further defines at least one second through hole 123 having an inner surface 1231. The second through hole 123 extends through the intermediate layer 12. In some embodiments, the second through hole 123 of the intermediate layer 12 extends through the bottommost circuit layer 24a (e.g., the first circuit layer 24a) of the upper conductive structure 2b and terminated at or on a topmost circuit layer (e.g., the second upper circuit layer 38′) of the lower conductive structure 3b. That is, the second through hole 123 of the intermediate layer 12 does not extend through the topmost circuit layer (e.g., the second upper circuit layer 38′) of the lower conductive structure 3b. The second through hole 123 of the intermediate layer 12 may expose a portion of the topmost circuit layer (e.g., the top surface of the second upper circuit layer 38′) of the lower conductive structure 3b. As shown in FIG. 3, the second through hole 123 of the intermediate layer 12 tapers downwardly; that is, a size of a top portion of the second through hole 123 is greater than a size of a bottom portion of the second through hole 123. Further, the second through hole 123 of the intermediate layer 12 is aligned with and in communication with the through holes 203 of the first dielectric layers 20 and the through hole 263 of the second dielectric layer 26. The bottom portion of the through hole 203 of the bottommost first dielectric layer 20 is disposed adjacent to or connected to the top portion of the second through hole 123 of the intermediate layer 12. The size of the bottom portion of the through hole 203 of the bottommost first dielectric layer 20 is substantially equal to the size of the top portion of the second through hole 123 of the intermediate layer 12. Thus, the inner surface 1231 of the second through hole 123 of the intermediate layer 12 is coplanar with or aligned with the inner surfaces 2031 of the through holes 203 of the first dielectric layers 20 and the inner surface 2631 of the through hole 263 of the second dielectric layer 26. In some embodiments, the inner surface 1231 of the second through hole 123 of the intermediate layer 12 is a curved surface, and is a portion of the inner surface 231 of the single, continuous through hole 23 for accommodating the upper through via 14. The second through hole 123 of the intermediate layer 12, the through holes 203 of the first dielectric layers 20 and the through hole 263 of the second dielectric layer 26 are collectively configured to form or define the single through hole 23. Thus, the single through hole 23 includes the second through hole 123 of the intermediate layer 12, the through holes 203 of the first dielectric layers 20 and the through hole 263 of the second dielectric layer 26.

As shown in FIG. 3, cross-sectional views of one side of the second through hole 123 of the intermediate layer 12, the inner surfaces 2031 of the through holes 203 of the first dielectric layers 20 and the inner surface 2631 of the through hole 263 of the second dielectric layer 26 are segments of a substantially straight line. That is, cross-sectional views of one side of the inner surface 1231 of the second through hole 123 of the intermediate layer 12, the inner surfaces 2031 of the through holes 203 of the first dielectric layers 20 and the inner surface 2631 of the through hole 263 of the second dielectric layer 26 may extend along the same substantially straight line. The single through hole 23 extends through the upper conductive structure 2b and the intermediate layer 12; that is, the single through hole 23 extends from the top surface 21 of the upper conductive structure 2b to the bottom portion of the intermediate layer 12 to expose a portion of the topmost circuit layer (e.g., the top surface of the second upper circuit layer 38′) of the lower conductive structure 3b. The single through hole 23 tapers downwardly. A maximum width (e.g., at the top portion) of the single through hole 23 may be about 25 μm to about 60 μm.

The upper through via 14 is formed or disposed in the single through hole 23. Thus, the upper through via 14 extends through at least a portion of the upper conductive structure 2b and the intermediate layer 12, and is electrically connected to the topmost circuit layer (e.g., the top surface of the second upper circuit layer 38′) of the lower conductive structure 3b. As shown in FIG. 3, the upper through via 14 extends through and contacts the bottommost circuit layer 24a (e.g., the first circuit layer 24a) of the upper conductive structure 2b, and terminates at or on, and contacts a portion of the topmost circuit layer (e.g., the top surface of the second upper circuit layer 38′) of the lower conductive structure 3b. The upper through via 14 extends from the top surface 21 of the upper conductive structure 2b to the bottom surface 122 of the intermediate layer 12. Thus, the upper through via 14 extends to contact a portion of the lower conductive structure 3b, and the upper through via 14 does not extend through the lower conductive structure 3b. Further, the upper through via 14 tapers downwardly; that is, a size of a top portion of the upper through via 14 is greater than a size of a bottom portion of the upper through via 14. Thus, a tapering direction of the inner vias 25 of the upper conductive structure 2b is different from a tapering direction of the upper through via 14. In some embodiments, the upper through via 14 is a monolithic structure or a one-piece structure, has a homogeneous material composition, and a peripheral surface 143 of the upper through via 14 is a substantially continuous surface without boundaries. The upper through via 14 may be covered by the outer circuit layer 28. Alternatively, or in combination, the upper through via 14 and the outer circuit layer 28 may be formed integrally as a monolithic or one-piece structure. As a result, the upper conductive structure 2b may be electrically connected to the lower conductive structure 3b through the upper through via 14 and the lower through via 15.

As shown in FIG. 3, the upper conductive structure 2b includes a high-density region 41 and a low-density region 47. In some embodiments, a density of a circuit line (including, for example, a trace or a pad) in the high-density region 41 is greater than a density of a circuit line in the low-density region 47. That is, the count of the circuit line (including, for example, the trace or the pad) in a unit area within the high-density region 41 is greater than the count of the circuit line in an equal unit area within the low-density region 47. Alternatively, or in combination, an L/S of a circuit layer within the high-density region 41 is less than an L/S of a circuit layer within the low-density region 47. Further, the upper through via 14 is disposed in the low-density region 47 of the high-density conductive structure (e.g., the upper conductive structure 2b). In some embodiments, the high-density region 41 may be a chip bonding area. In addition, a size of an end portion (e.g., the bottom portion) of the upper through via 14 is substantially equal to a size of an end portion (e.g., a top portion) of the lower through via 15. The upper through via 14 does not contact or directly connect to the lower through via 15.

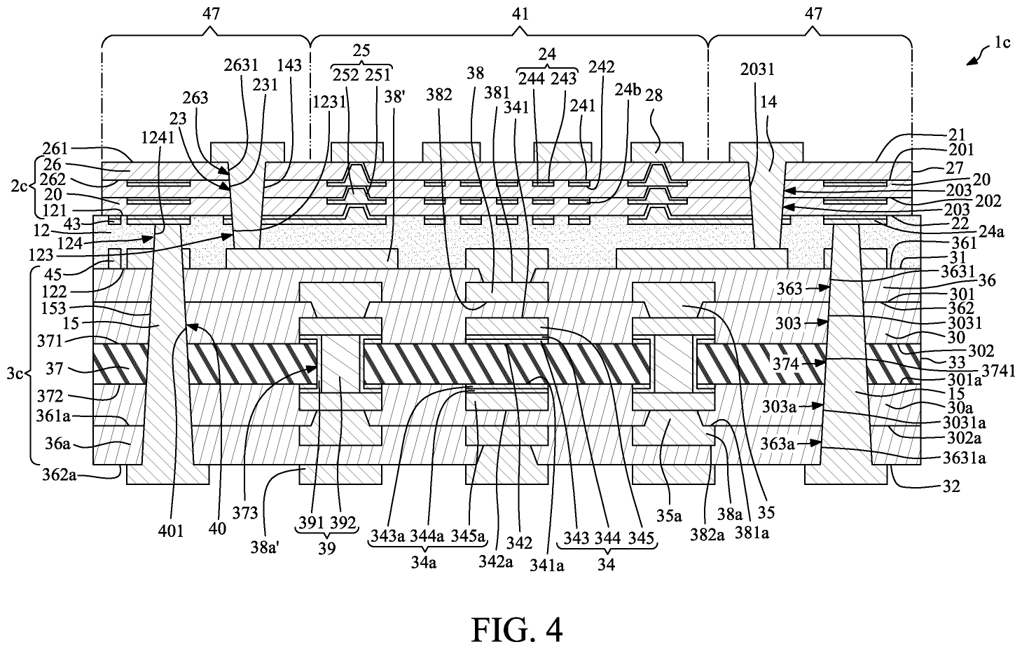

FIG. 4 illustrates a cross-sectional view of a wiring structure 1c according to some embodiments of the present disclosure. The wiring structure 1c is similar to the wiring structure 1b shown in FIG. 3, except for structures of an upper conductive structure 2c and a lower conductive structure 3c. As shown in FIG. 4, the upper conductive structure 2c and the lower conductive structure 3c are both strip structures. Thus, the wiring structure 1c is a strip structure. In some embodiments, the lower conductive structure 3c may be a panel structure that carries a plurality of strip upper conductive structures 2c. Thus, the wiring structure 1c is a panel structure. The upper conductive structure 2c includes at least one chip bonding area 41 for receiving at least one semiconductor chip 42 (FIG. 5), and a length (e.g., about 240 mm) of the upper conductive structure 2c is greater than a width (e.g., about 95 mm) of the upper conductive structure 2c from a top view. Further, a length of the lower conductive structure 3c is greater than a width of the lower conductive structure 3c from a top view. In addition, the lateral peripheral surface 27 of the upper conductive structure 2c is not coplanar with (e.g., inwardly recessed from or otherwise displaced from) the lateral peripheral surface 33 of the lower conductive structure 3c. In some embodiments, during a manufacturing process, the lower conductive structure 3c and the upper conductive structure 2c may be both known good strip structures. Alternatively, the upper conductive structure 2c may be a known good strip structure, and the lower conductive structure 3c may be a known good panel structure. As a result, the yield of the wiring structure 1c may be further improved.

As shown in FIG. 4, the upper conductive structure 2c includes at least one fiducial mark 43 at a corner thereof, and the lower conductive structure 3c includes at least one fiducial mark 45 at a corner thereof. The fiducial mark 43 of the upper conductive structure 2c is aligned with the fiducial mark 45 of the lower conductive structure 3c during a manufacturing process, so that the relative position of the upper conductive structure 2c and the lower conductive structure 3c is secured.

FIG. 5 illustrates a cross-sectional view of a bonding of a package structure 4 and a substrate 46 according to some embodiments. The package structure 4 includes a wiring structure 1d, a semiconductor chip 42, a plurality of first connecting elements 44 and a plurality of second connecting elements 48. The wiring structure 1d of FIG. 5 is similar to the wiring structure 1b shown in FIG. 3, except for structures of an upper conductive structure 2d and a lower conductive structure 3d. The upper conductive structure 2d and the lower conductive structure 3d are both dice and may be singulated concurrently. Thus, the wiring structure 1d is a unit structure. That is, a lateral peripheral surface 27d of the upper conductive structure 2d, a lateral peripheral surface 33d of the lower conductive structure 3d and a lateral peripheral surface of the intermediate layer 12 are substantially coplanar with each other. The semiconductor chip 42 is electrically connected and bonded to the outer circuit layer 28 of the upper conductive structure 2d through the first connecting elements 44 (e.g., solder bumps or other conductive bumps). The second lower circuit layer 38a′ of the lower conductive structure 3d is electrically connected and bonded to the substrate 46 (e.g., a mother board such as a printed circuit board (PCB)) through the second connecting elements 48 (e.g., solder bumps or other conductive bumps).

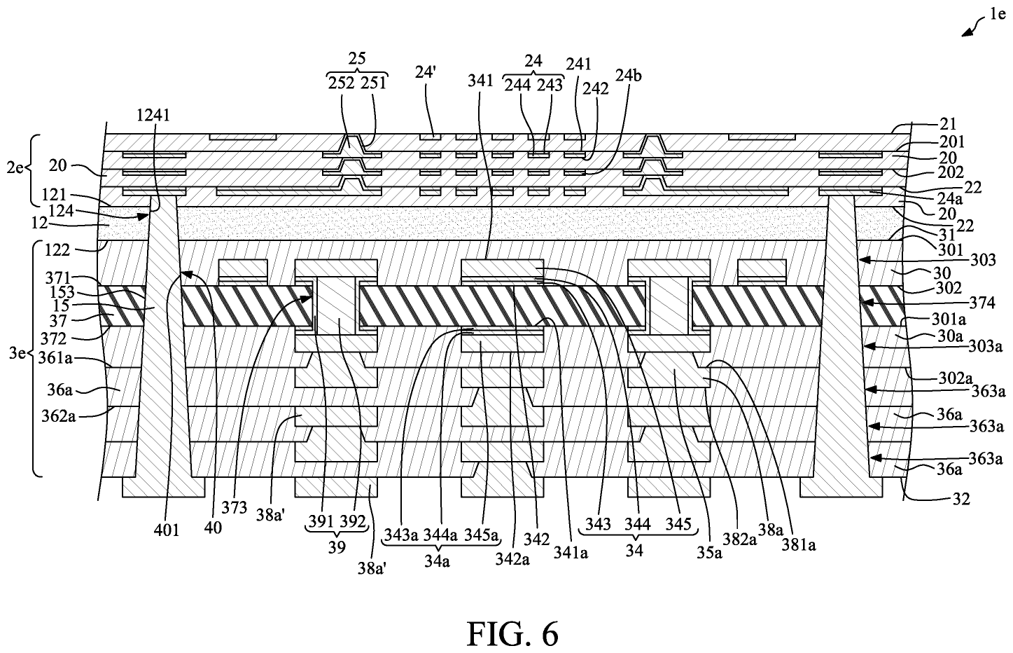

FIG. 6 illustrates a cross-sectional view of a wiring structure 1e according to some embodiments of the present disclosure. The wiring structure le is similar to the wiring structure 1 shown in FIG. 1, except for structures of an upper conductive structure 2e and a lower conductive structure 3e. In the upper conductive structure 2e, the second dielectric layer 26 is replaced by a topmost first dielectric layer 20. In addition, the upper conductive structure 2e may further include a topmost circuit layer 24′. The topmost circuit layer 24′ may omit a seed layer, and may be electrically connected to the below circuit layer 24 through the inner vias 25. A top surface of the topmost circuit layer 24′ may be substantially coplanar with the top surface 21 of the upper conductive structure 2e (e.g., the top surface 201 of the topmost first dielectric layer 20). Thus, the top surface of the topmost circuit layer 24′ may be exposed from the top surface 21 of the upper conductive structure 2e (e.g., the top surface 201 of the topmost first dielectric layer 20). Further, the bottommost first dielectric layer 20 may cover the bottommost circuit layer 24a (e.g., the first circuit layer 24a). Thus, the entire bottom surface 22 of the upper conductive structure 2e (e.g., the bottom surface 202 of the bottommost first dielectric layer 20) is substantially flat.

In the lower conductive structure 3e, the second upper dielectric layer 36 and the second upper circuit layers 38, 38′ are omitted. Thus, the top surface 31 of the lower conductive structure 3e is the top surface 301 of first upper dielectric layer 30, which is substantially flat. Further, two additional second lower dielectric layers 36a and two additional second lower circuit layers 38a′ are further included.

The intermediate layer 12 adheres to the bottom surface 22 of the upper conductive structure 2e and the top surface 31 of the lower conductive structure 3e. Thus, the entire top surface 121 and the entire bottom surface 122 of the intermediate layer 12 are both substantially flat. The intermediate layer 12 does not include or contact a horizontally extending or connecting circuit layer. That is, there is no horizontally extending or connecting circuit layer disposed or embedded in the intermediate layer 12. The lower through via 15 extends through the lower conductive structure 3e and the intermediate layer 12, and further extends into a portion (e.g., the bottommost first dielectric layer 20) of the upper conductive structure 2e to contact the bottommost first circuit layer 24a.

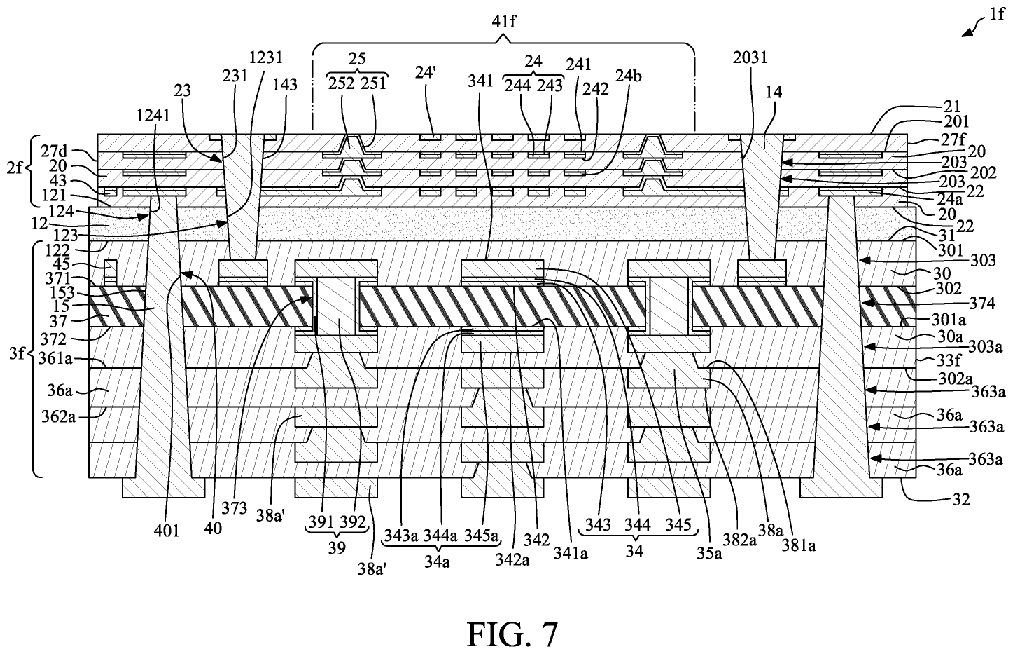

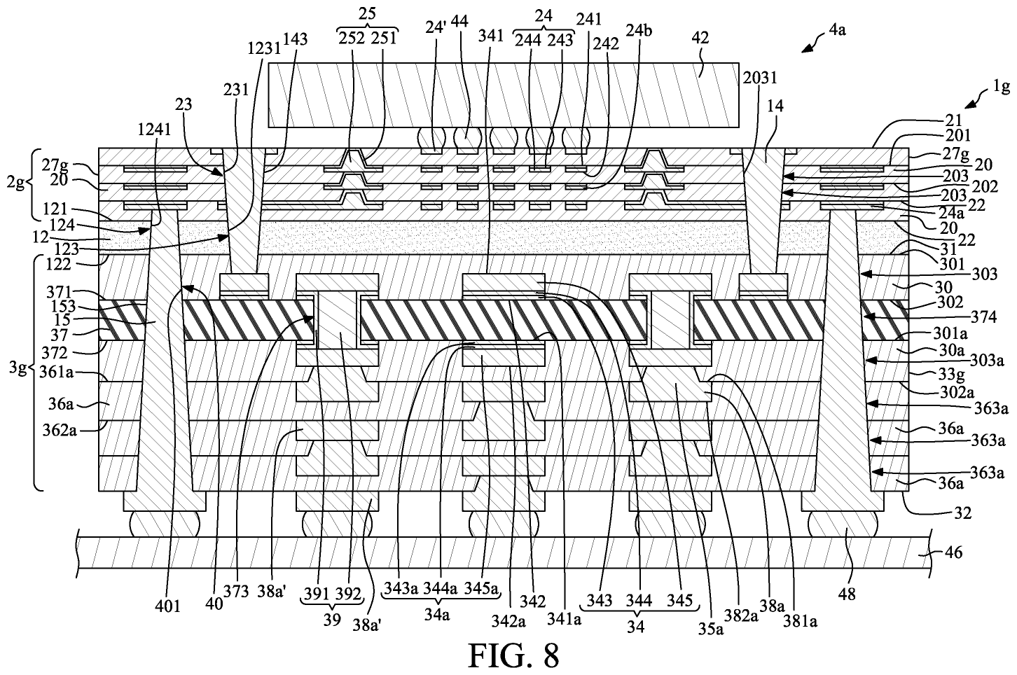

FIG. 7 illustrates a cross-sectional view of a wiring structure 1f according to some embodiments of the present disclosure. The wiring structure 1f is similar to the wiring structure 1e shown in FIG. 6, except for structures of an upper conductive structure 2f and a lower conductive structure 3f As shown in FIG. 7, the upper conductive structure 2f and the lower conductive structure 3f are both strip structures. Thus, the wiring structure 1f is a strip structure. In some embodiments, the lower conductive structure 3f may be a panel structure that carries a plurality of strip upper conductive structures 2f Thus, the wiring structure 1f is a panel structure. The upper conductive structure 2f includes at least one chip bonding area 41f for receiving at least one semiconductor chip 42 (FIG. 8). In addition, a lateral peripheral surface 27f of the upper conductive structure 2f is not coplanar with (e.g., inwardly recessed from or otherwise displaced from) a lateral peripheral surface 33f of the lower conductive structure 3f. In some embodiments, the upper through via 14 may be further included to extend through and contact the topmost circuit layer 24′. The upper through via 14 extends through the upper conductive structure 2f and the intermediate layer 12, and further extends into a portion (e.g., the first upper dielectric layer 30) of the lower conductive structure 3f to contact the first upper circuit layer 34.

As shown in FIG. 7, the upper conductive structure 2f includes at least one fiducial mark 43 at a corner thereof, and the lower conductive structure 3f includes at least one fiducial mark 45 at a corner thereof. The fiducial mark 43 of the upper conductive structure 2f is aligned with the fiducial mark 45 of the lower conductive structure 3f during a manufacturing process, so that the relative position of the upper conductive structure 2f and the lower conductive structure 3f is secured.

FIG. 8 illustrates a cross-sectional view of a bonding of a package structure 4a and a substrate 46. The package structure 4a includes a wiring structure 1g, a semiconductor chip 42, a plurality of first connecting elements 44 and a plurality of second connecting elements 48. The wiring structure 1g of FIG. 8 is similar to the wiring structure 1e shown in FIG. 6, except for structures of an upper conductive structure 2g and a lower conductive structure 3g. The upper conductive structure 2g and the lower conductive structure 3g are both dice and may be singulated concurrently. Thus, the wiring structure 1g is a unit structure. That is, a lateral peripheral surface 27g of the upper conductive structure 2g, a lateral peripheral surface 33g of the lower conductive structure 3g and a lateral peripheral surface of the intermediate layer 12 are substantially coplanar with each other. In addition, the upper through vias 14 are further included. The semiconductor chip 42 is electrically connected and bonded to the topmost circuit layer 24′ of the upper conductive structure 2g through the first connecting elements 44 (e.g., solder bumps or other conductive bumps). The bottommost second lower circuit layer 38a′ of the lower conductive structure 3g is electrically connected and bonded to the substrate 46 (e.g., a mother board such as a PCB) through the second connecting elements 48 (e.g., solder bumps or other conductive bumps).

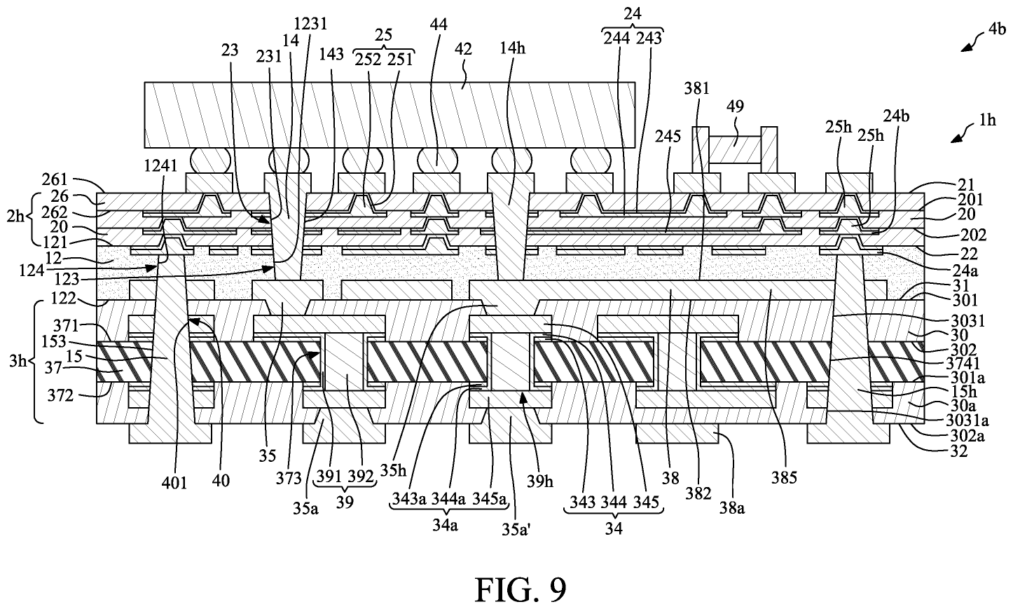

FIG. 9 illustrates a cross-sectional view of a package structure 4b according to some embodiments of the present disclosure. The package structure 4b includes a wiring structure 1h, a semiconductor chip 42, and a plurality of first connecting elements 44. The wiring structure 1h of FIG. 9 is similar to the wiring structure 1d shown in FIG. 5, except for structures of an upper conductive structure 2h and a lower conductive structure 3h. In the upper conductive structure 2h, at least one upper through via 14h is disposed under the semiconductor chip 42, and one of the circuit layers (e.g., the second circuit layer 24b) may include one or more traces (e.g., high-density traces) and a ground plane 245 for grounding. In some embodiments, a plurality of upper through vias 14h may be disposed parallel or laterally adjacent to each other to form a first via wall (or a fence structure). Further, a plurality of inner vias 25h may be stacked on each other to form a columnar structure, and a plurality of columnar structures may be disposed parallel or laterally adjacent to each other to form a second via wall (or a fence structure). The upper conductive structure 2h can provide a signal transmission between semiconductor chips 42, between a semiconductor chip 42 and a passive component 49, and/or between passive components 49. Such transmitted signals may exclude power signals. For example, the upper conductive structure 2h can provide excellent stability of signal transmissions of radio frequency (RF) signals and high-speed digital signals. The high-speed digital signals and RF/analog modulation signals can be arranged on the same layer or on different layers. In order to prevent the RF/analog modulation signals from being interfered by the high-speed digital signals, two kinds of layouts for two situations may be designed as follows. In the first situation that the high-speed digital signals and RF/analog modulation signals are arranged on the same layer, the above-mentioned first via wall or second via wall can achieve a function of signal isolation. That is, the first via wall or the second via wall can be disposed between the high-speed digital signals and the RF/analog modulation signals. In the second situation that the high-speed digital signals and RF/analog modulation signals are arranged on the different layers, the above-mentioned ground plane 245 can achieve a function of signal isolation. That is, the ground plane 245 can be disposed between the high-speed digital signals and the RF/analog modulation signals.

In the lower conductive structure 3h, the second upper circuit layer 38′, the second upper dielectric layer 36, the second lower circuit layer 38a′ and the second lower dielectric layer 36a are omitted. Further, a lower through via 15h may be disposed under the stacked inner vias 25h, and one of the circuit layers (e.g., the second upper circuit layers 38) may include one or more traces (e.g., low-density traces) and a ground plane 385 for grounding. The lower conductive structure 3h can provide a power signal transmission between semiconductor chips 42, between a semiconductor chip 42 and a passive component 49, and/or between passive components 49. It is noted that the circuit layers (e.g., the upper circuit layers 34, 38 and the lower circuit layers 34a, 38a) has the characteristic of low direct current (DC) impedance and low parasitic capacitance. Further, the ground plane 385 can achieve a function of signal isolation between the lower conductive structure 3h and the upper conductive structure 2h.

The common grounding of the wiring structure 1h can be achieved by the following two paths. The first path is a combination of the ground plane 245, the ground plane 385, the upper through via 14h, an upper interconnection via 35h, an interconnection via 39h and a lower interconnection via 35a′. The second path is a combination of the ground plane 245, the ground plane 385, the stacked inner vias 25h and the lower through via 15h. In addition, the first via wall may further include the upper interconnection via 35h, the interconnection via 39h and the lower interconnection via 35a′ under the upper through via 14h to form an extended first via wall. The second via wall may further include the lower through via 15h under the stacked inner vias 25h to form an extended second via wall. The extended first via wall and the extended second via wall can prevent the signals from leaking when they are disposed adjacent to the lateral peripheral surface of the wiring structure 1h.

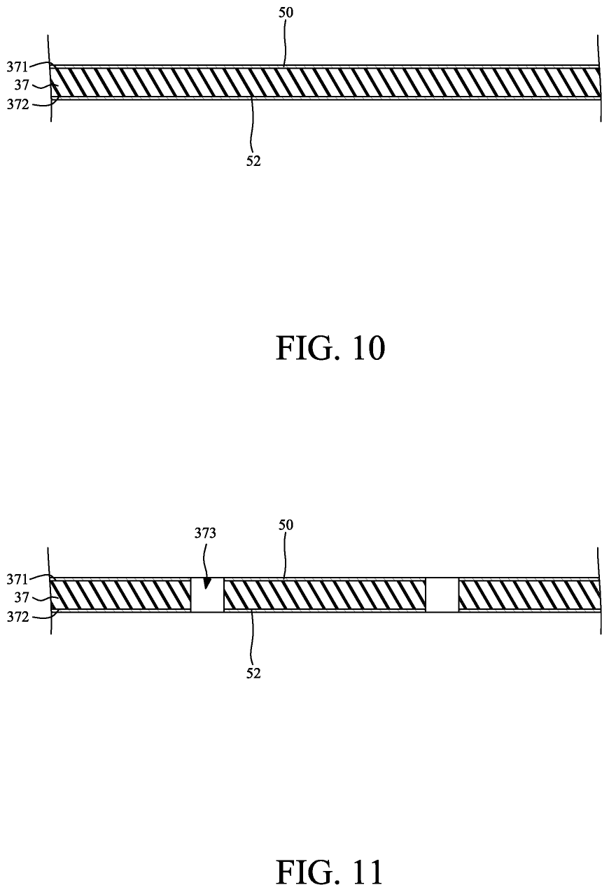

FIG. 10 through FIG. 47 illustrate a method for manufacturing a wiring structure according to some embodiments of the present disclosure. In some embodiments, the method is for manufacturing the wiring structure 1 shown in FIG. 1.

Referring to FIG. 10 through FIG. 29, a lower conductive structure 3 is provided. The lower conductive structure 3 is manufactured as follows. Referring to FIG. 10, a core portion 37 with a top copper foil 50 and a bottom copper foil 52 is provided. The core portion 37 may be in a wafer type, a panel type or a strip type. The core portion 37 has a top surface 371 and a bottom surface 372 opposite to the top surface 371. The top copper foil 50 is disposed on the top surface 371 of the core portion 37, and the bottom copper foil 52 is disposed on the bottom surface 372 of the core portion 37.

Referring to FIG. 11, a plurality of first through holes 373 are formed to extend through the core portion 37, the top copper foil 50 and the bottom copper foil 52 by a drilling technique (such as laser drilling or mechanical drilling) or other suitable techniques.

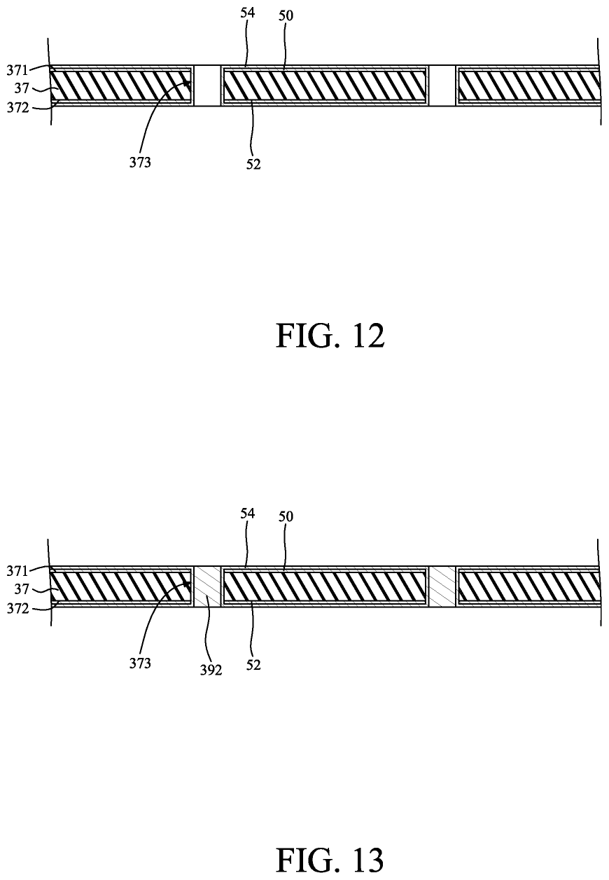

Referring to FIG. 12, a second metallic layer 54 is formed or disposed on the top copper foil 50, the bottom copper foil 52 and side walls of the first through holes 373 by a plating technique or other suitable techniques. A portion of the second metallic layer 54 on the side wall of each first through hole 373 defines a central through hole.

Referring to FIG. 13, an insulation material 392 is disposed to fill the central through hole defined by the second metallic layer 54.

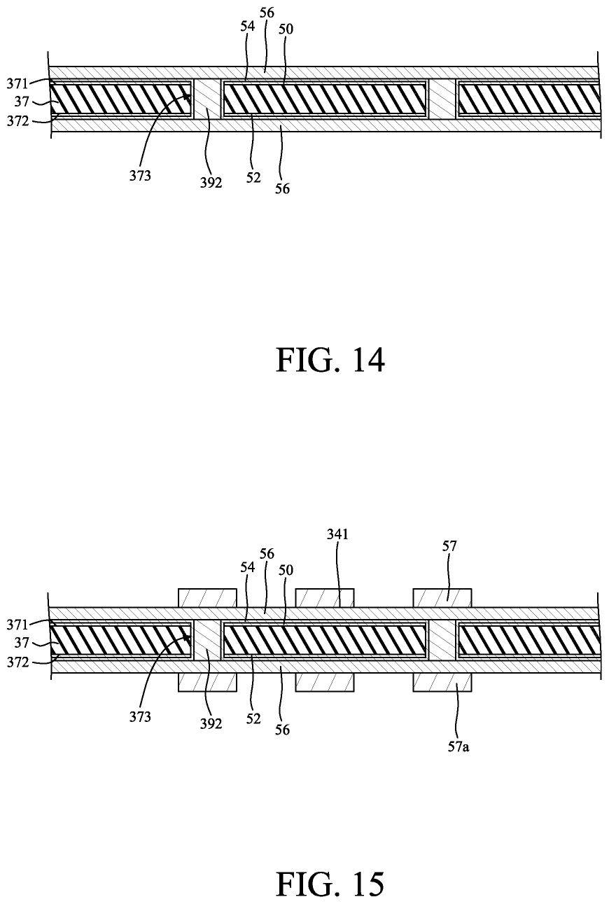

Referring to FIG. 14, a top third metallic layer 56 and a bottom third metallic layer 56 are formed or disposed on the second metallic layer 54 by a plating technique or other suitable techniques. The third metallic layers 56 cover the insulation material 392.

Referring to FIG. 15, a top photoresist layer 57 is formed or disposed on the top third metallic layer 56, and a bottom photoresist layer 57a is formed or disposed on the bottom third metallic layer 56. Then, the photoresist layers 57, 57a are patterned by exposure and development.

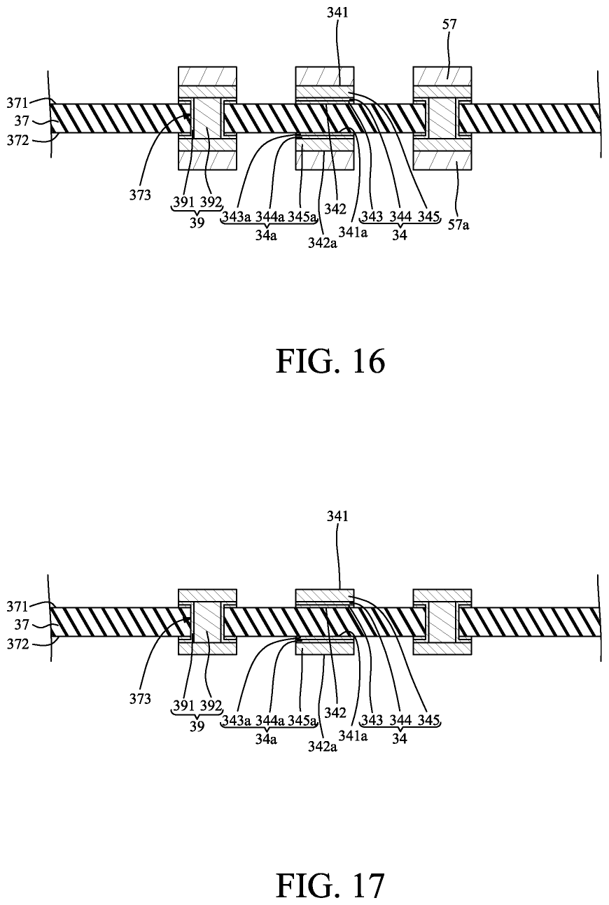

Referring to FIG. 16, portions of the top copper foil 50, the second metallic layer 54 and the top third metallic layer 56 that are not covered by the top photoresist layer 57 are removed by an etching technique or other suitable techniques. Portions of the top copper foil 50, the second metallic layer 54 and the top third metallic layer 56 that are covered by the top photoresist layer 57 remain to form a first upper circuit layer 34. Meanwhile, portions of the bottom copper foil 52, the second metallic layer 54 and the bottom third metallic layer 56 that are not covered by the bottom photoresist layer 57a are removed by an etching technique or other suitable techniques. Portions of the bottom copper foil 52, the second metallic layer 54 and the bottom third metallic layer 56a that are covered by the bottom photoresist layer 57a remain to form a first lower circuit layer 34a. Meanwhile, portions of the second metallic layer 54 and the insulation material 392 that are disposed in the first through hole 373 form an interconnection via 39. As shown in FIG. 16, the first upper circuit layer 34 has a top surface 341 and a bottom surface 342 opposite to the top surface 341. In some embodiments, the first upper circuit layer 34 is formed or disposed on the top surface 371 of the core portion 37. The bottom surface 342 of the first upper circuit layer 34 contacts the top surface 371 of the core portion 37. In some embodiments, the first upper circuit layer 34 may include a first metallic layer 343, a second metallic layer 344 and a third metallic layer 345. The first metallic layer 343 is disposed on the top surface 371 of the core portion 37, and may be formed from a portion of the top copper foil 50. The second metallic layer 344 is disposed on the first metallic layer 343, and may be a plated copper layer formed from the second metallic layer 54. The third metallic layer 345 is disposed on the second metallic layer 344, and may be another plated copper layer formed from the top third metallic layer 56.

The first lower circuit layer 34a has a top surface 341a and a bottom surface 342a opposite to the top surface 341a. In some embodiments, the first lower circuit layer 34a is formed or disposed on the bottom surface 372 of the core portion 37. The top surface 341a of the first lower circuit layer 34a contacts the bottom surface 372 of the core portion 37. In some embodiments, the first lower circuit layer 34a may include a first metallic layer 343a, a second metallic layer 344a and a third metallic layer 345a. The first metallic layer 343a is disposed on the bottom surface 372 of the core portion 37, and may be formed from a portion of the bottom copper foil 52. The second metallic layer 344a is disposed on the first metallic layer 343a, and may be a plated copper layer formed from the second metallic layer 54. The third metallic layer 345a is disposed on the second metal layer 344a, and may be another plated copper layer formed from the bottom third metallic layer 56. The interconnection via 39 includes a base metallic layer 391 made from the second metallic layer 54 and the insulation material 392. In some embodiments, the interconnection via 39 may include a bulk metallic material that fills the first through hole 373. The interconnection via 39 electrically connects the first upper circuit layer 34 and the first lower circuit layer 34a.

Referring to FIG. 17, the top photoresist layer 57 and the bottom photoresist layer 57a are removed by a stripping technique or other suitable techniques.

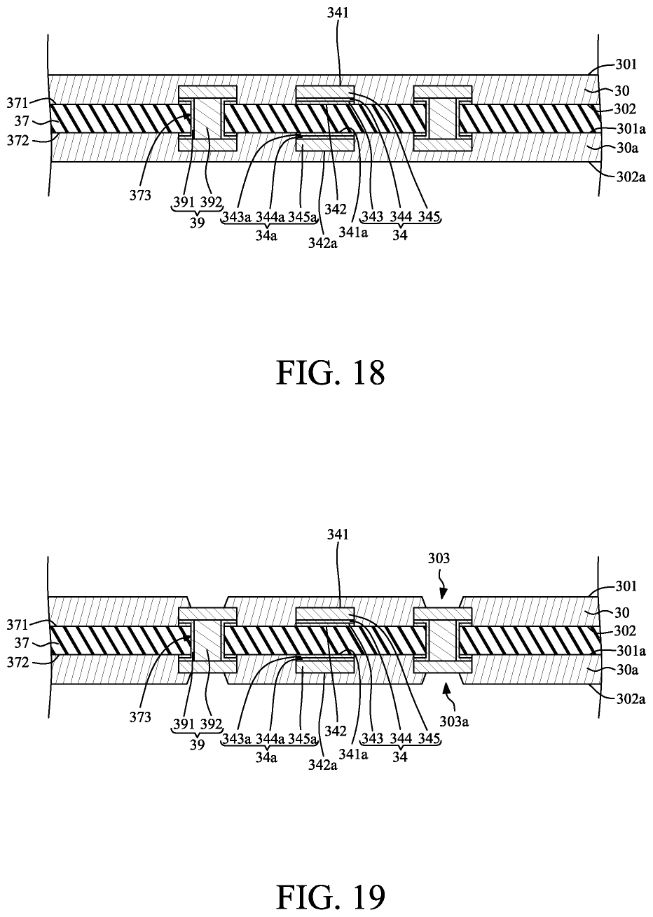

Referring to FIG. 18, a first upper dielectric layer 30 is formed or disposed on the top surface 371 of the core portion 37 to cover the top surface 371 of the core portion 37 and the first upper circuit layer 34 by a lamination technique or other suitable techniques. Meanwhile, a first lower dielectric layer 30a is formed or disposed on the bottom surface 372 of the core portion 37 to cover the bottom surface 372 of the core portion 37 and the first lower circuit layer 34a by a lamination technique or other suitable techniques.

Referring to FIG. 19, at least one through hole 303 is formed to extend through the first upper dielectric layer 30 to expose a portion of the first upper circuit layer 34 by a drilling technique or other suitable techniques. Meanwhile, at least one through hole 303a is formed to extend through the first lower dielectric layer 30a to expose a portion of the first lower circuit layer 34a by a drilling technique or other suitable techniques.

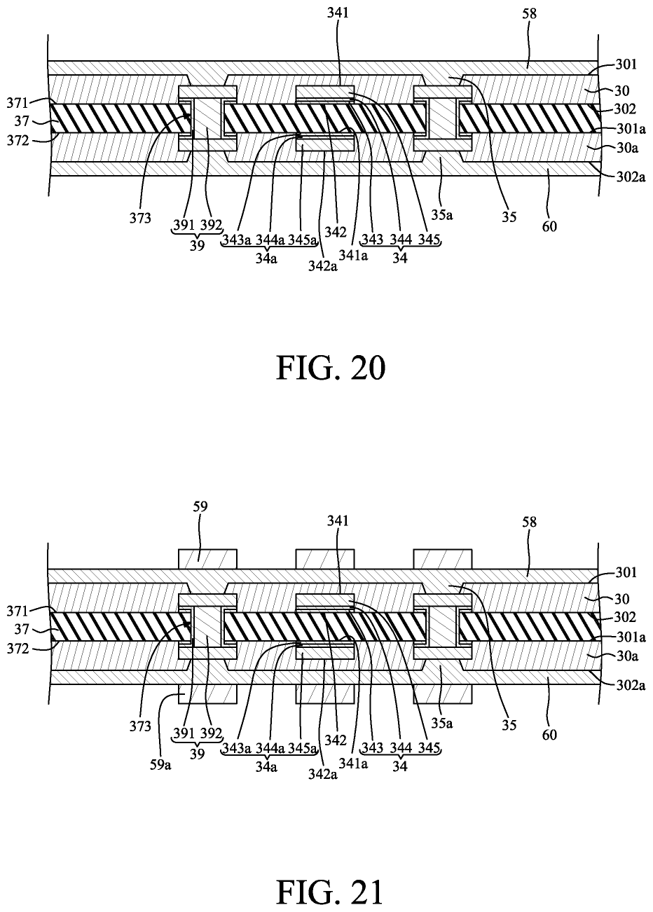

Referring to FIG. 20, a top metallic layer 58 is formed on the first upper dielectric layer 30 and in the through hole 303 to form an upper interconnection via 35 by a plating technique or other suitable techniques. Meanwhile, a bottom metallic layer 60 is formed on the first lower dielectric layer 30a and in the through hole 303a to form a lower interconnection via 35a by a plating technique or other suitable techniques. As shown in FIG. 20, the upper interconnection via 35 tapers downwardly, and the lower interconnection via 35a tapers upwardly.

Referring to FIG. 21, a top photoresist layer 59 is formed or disposed on the top metallic layer 58, and a bottom photoresist layer 59a is formed or disposed on the bottom metallic layer 60. Then, the photoresist layers 59, 59a are patterned by exposure and development.

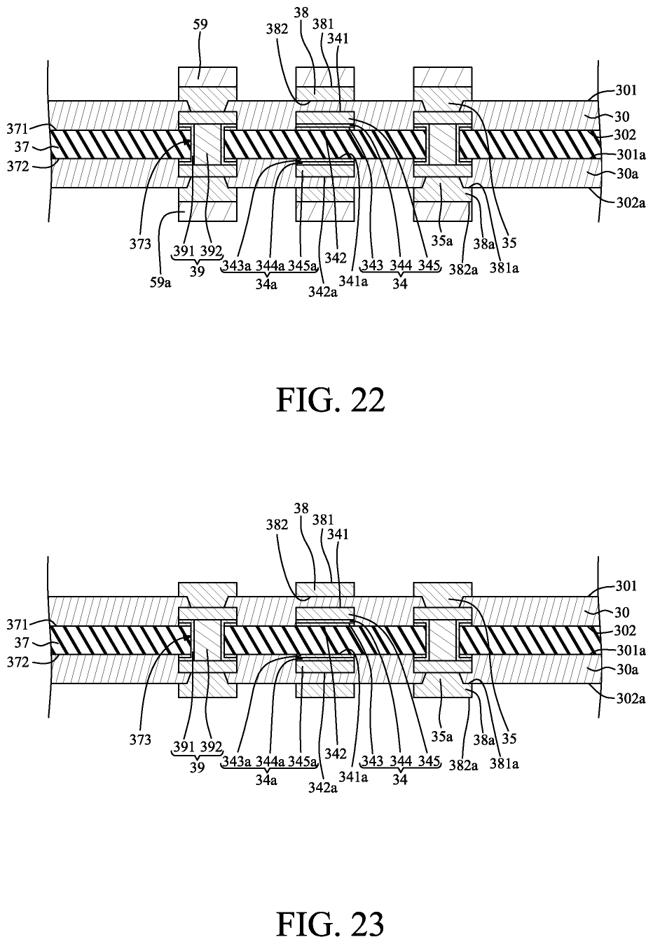

Referring to FIG. 22, portions of the top metallic layer 58 that are not covered by the top photoresist layer 59 are removed by an etching technique or other suitable techniques. Portions of the top metallic layer 58 that are covered by the top photoresist layer 59 remain to form a second upper circuit layer 38. Meanwhile, portions of the bottom metallic layer 60 that are not covered by the bottom photoresist layer 59a are removed by an etching technique or other suitable techniques. Portions of the bottom metallic layer 60 that are covered by the bottom photoresist layer 59a remain to form a second lower circuit layer 38a.

Referring to FIG. 23, the top photoresist layer 59 and the bottom photoresist layer 59a are removed by a stripping technique or other suitable techniques.

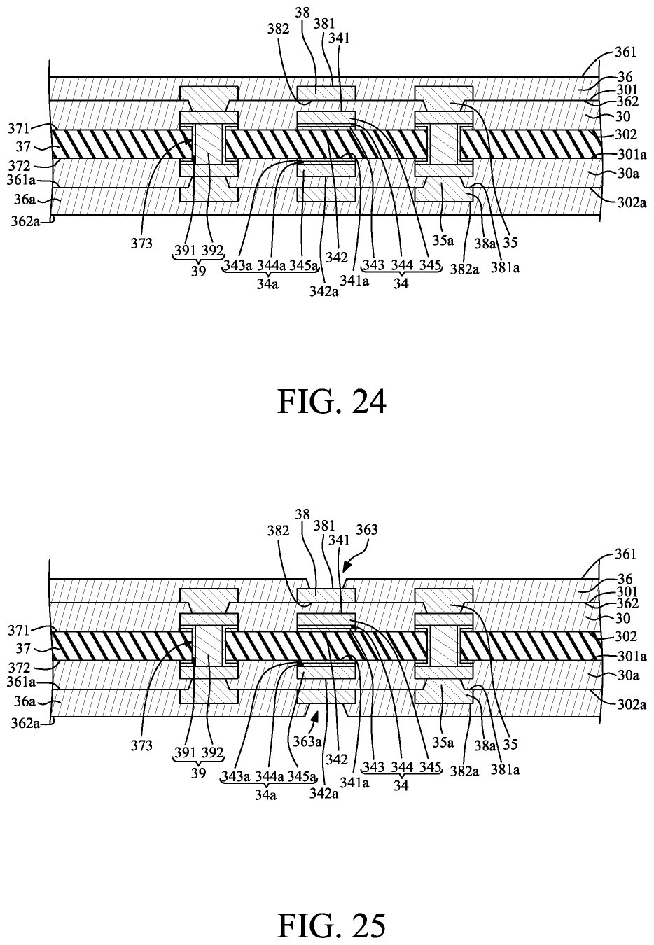

Referring to FIG. 24, a second upper dielectric layer 36 is formed or disposed on the top surface 301 of the first upper dielectric layer 30 to cover the top surface 301 of the first upper dielectric layer 30 and the second upper circuit layer 38 by a lamination technique or other suitable techniques. Meanwhile, a second lower dielectric layer 36a is formed or disposed on the bottom surface 302a of the first lower dielectric layer 30a to cover the bottom surface 302a of the first lower dielectric layer 30a and the second lower circuit layer 38a by a lamination technique or other suitable techniques.

Referring to FIG. 25, at least one through hole 363 is formed to extend through the second upper dielectric layer 36 to expose a portion of the second upper circuit layer 38 by a drilling technique or other suitable techniques. Meanwhile, at least one through hole 363a is formed to extend through the second lower dielectric layer 36a to expose a portion of the second lower circuit layer 38a by a drilling technique or other suitable techniques.

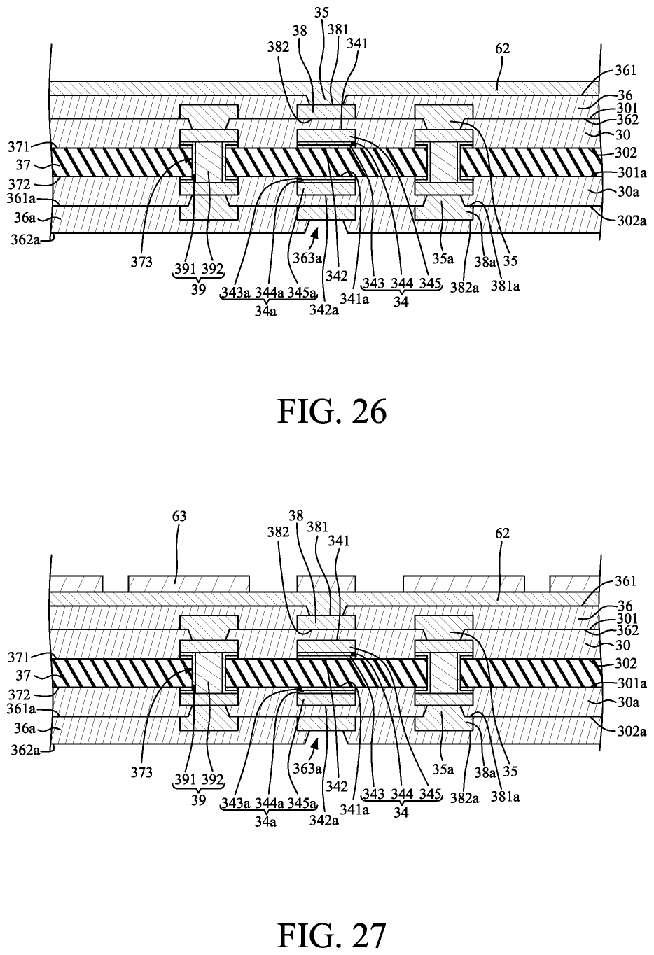

Referring to FIG. 26, a top metallic layer 62 is formed on the second upper dielectric layer 36 and in the through hole 363 to form an upper interconnection via 35 by a plating technique or other suitable techniques.

Referring to FIG. 27, a top photoresist layer 63 is formed or disposed on the top metallic layer 62. Then, the top photoresist layer 63 is patterned by exposure and development.

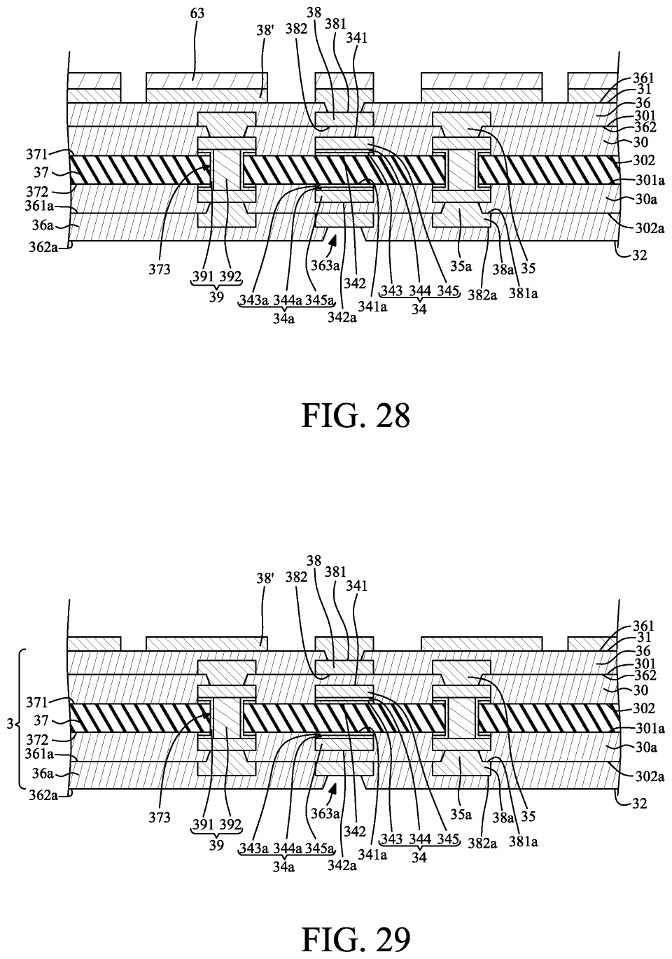

Referring to FIG. 28, portions of the top metallic layer 62 that are not covered by the top photoresist layer 63 are removed by an etching technique or other suitable techniques. Portions of the top metallic layer 62 that are covered by the top photoresist layer 63 remain to form a second upper circuit layer 38′.

Referring to FIG. 29, the top photoresist layer 63 is removed by a stripping technique or other suitable techniques. Meanwhile, the lower conductive structure 3 is formed, and the dielectric layers (including, the first upper dielectric layer 30, the second upper dielectric layer 36, the first lower dielectric layer 30a and the second lower dielectric layer 36a) are cured. At least one of the circuit layers (including, for example, one first upper circuit layer 34, two second upper circuit layers 38, 38′, one first lower circuit layer 34a and the second lower circuit layer 38a) is in contact with at least one of the dielectric layers (e.g., the first upper dielectric layer 30, the second upper dielectric layer 36, the first lower dielectric layer 30a and the second lower dielectric layer 36a). Then, an electrical property (such as open circuit/short circuit) of the lower conductive structure 3 is tested.

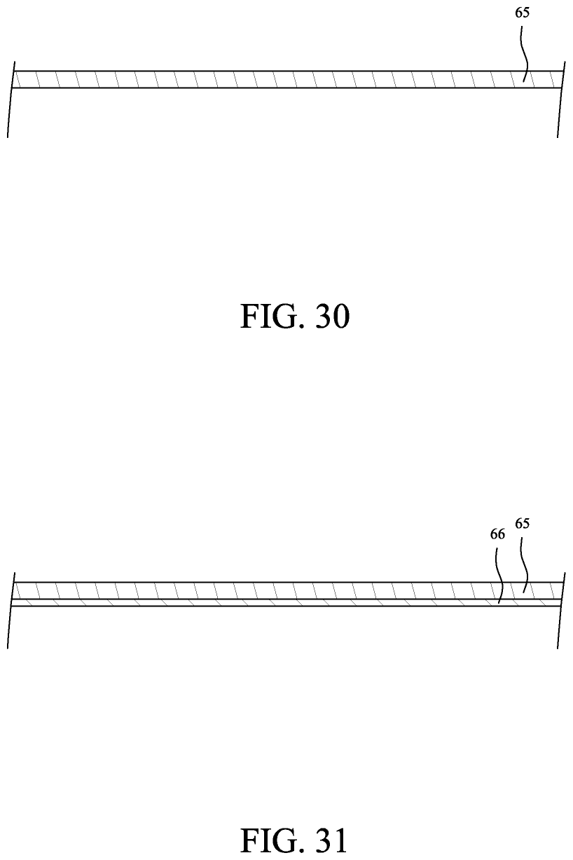

Referring to FIG. 30 through FIG. 40, an upper conductive structure 2 is provided. The upper conductive structure 2 is manufactured as follows. Referring to FIG. 30, a carrier 65 is provided. The carrier 65 may be a glass carrier, and may be in a wafer type, a panel type or a strip type.

Referring to FIG. 31, a release layer 66 is coated on a bottom surface of the carrier 65.

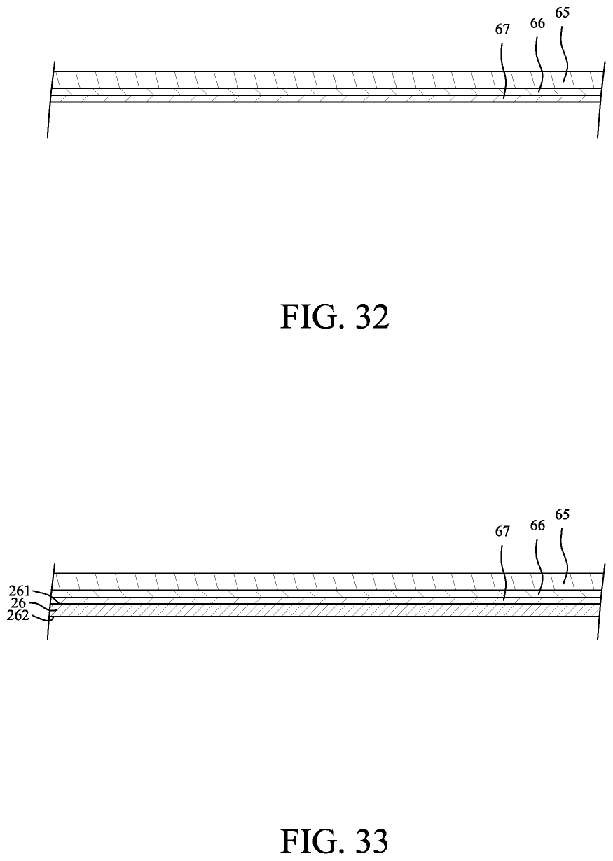

Referring to FIG. 32, a conductive layer 67 (e.g., a seed layer) is formed or disposed on the release layer 66 by a physical vapor deposition (PVD) technique or other suitable techniques.

Referring to FIG. 33, a second dielectric layer 26 is formed on the conductive layer 67 by a coating technique or other suitable techniques.

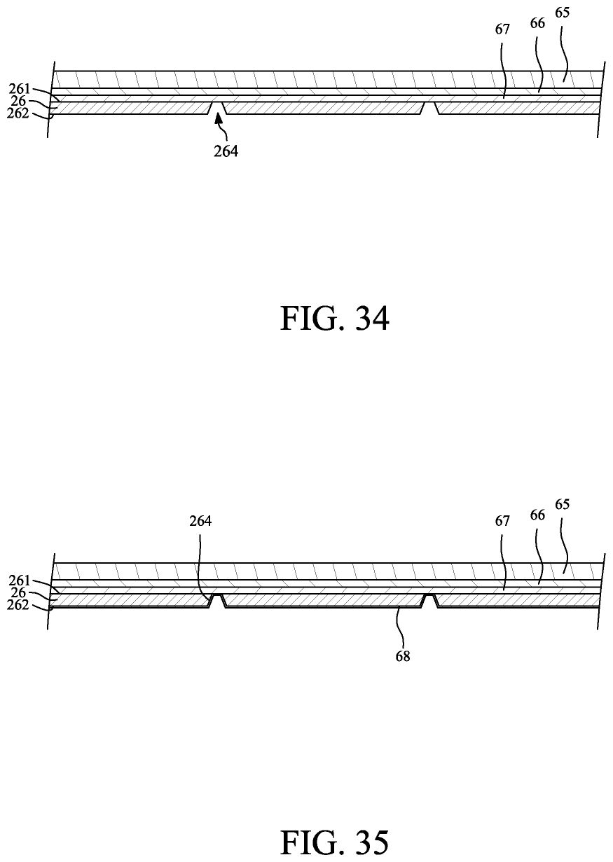

Referring to FIG. 34, at least one through hole 264 is formed to extend through the second dielectric layer 26 to expose a portion of the conductive layer 67 by an exposure and development technique or other suitable techniques.

Referring to FIG. 35, a seed layer 68 is formed on a bottom surface 262 of the second dielectric layer 26 and in the through hole 264 by a PVD technique or other suitable techniques.

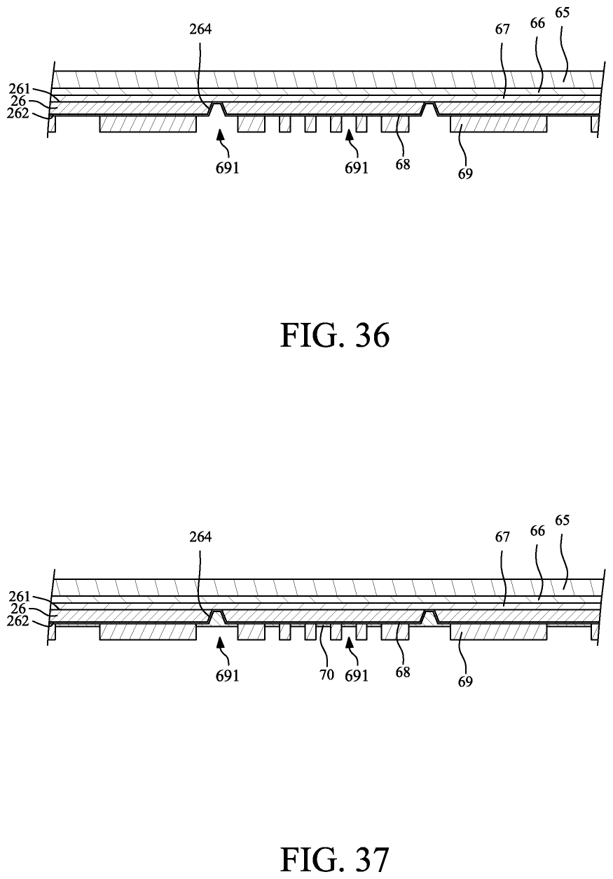

Referring to FIG. 36, a photoresist layer 69 is formed on the seed layer 68. Then, the photoresist layer 69 is patterned to expose portions of the seed layer 68 by an exposure and development technique or other suitable techniques. The photoresist layer 69 defines a plurality of openings 691. At least one opening 691 of the photoresist layer 69 corresponds to, and is aligned with, the through hole 264 of the second dielectric layer 26.

Referring to FIG. 37, a conductive metallic material 70 is disposed in the openings 691 of the photoresist layer 69 and on the seed layer 68 by a plating technique or other suitable techniques.

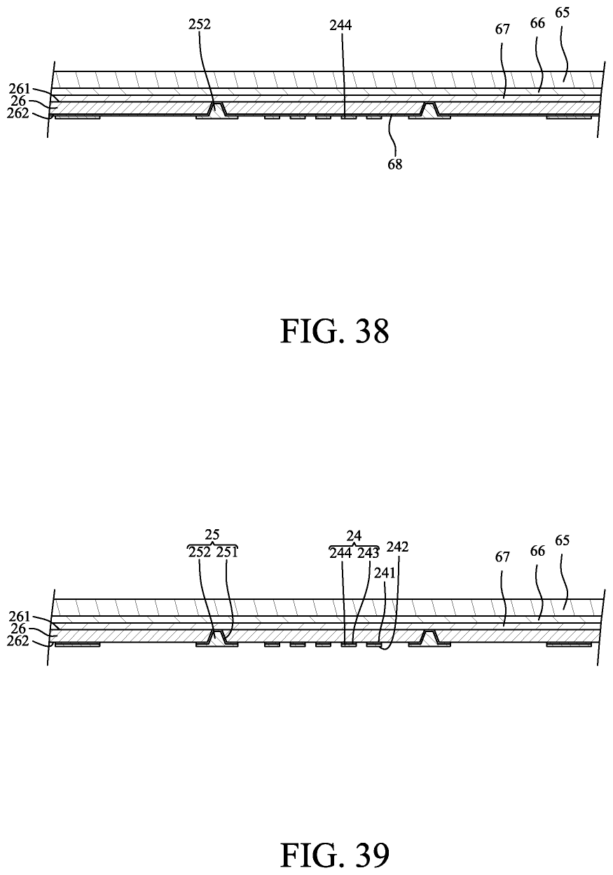

Referring to FIG. 38, the photoresist layer 69 is removed by a stripping technique or other suitable techniques.

Referring to FIG. 39, portions of the seed layer 68 that are not covered by the conductive metallic material 70 are removed by an etching technique or other suitable techniques. Meanwhile, a circuit layer 24 and at least one inner via 25 are formed. The circuit layer 24 may be a fan-out circuit layer or an RDL, and an L/S of the circuit layer 24 may be less than or equal to about 2 μm/about 2 μm, or less than or equal to about 1.8 μm/about 1.8 μm. The circuit layer 24 is disposed on the bottom surface 262 of the second dielectric layer 26. In some embodiments, the circuit layer 24 may include a seed layer 243 formed from the seed layer 68 and a conductive metallic material 244 disposed on the seed layer 243 and formed from the conductive metallic material 70. The inner via 25 is disposed in the through hole 264 of the second dielectric layer 26. In some embodiments, the inner via 25 may include a seed layer 251 and a conductive metallic material 252 disposed on the seed layer 251. The inner via 25 tapers upwardly.

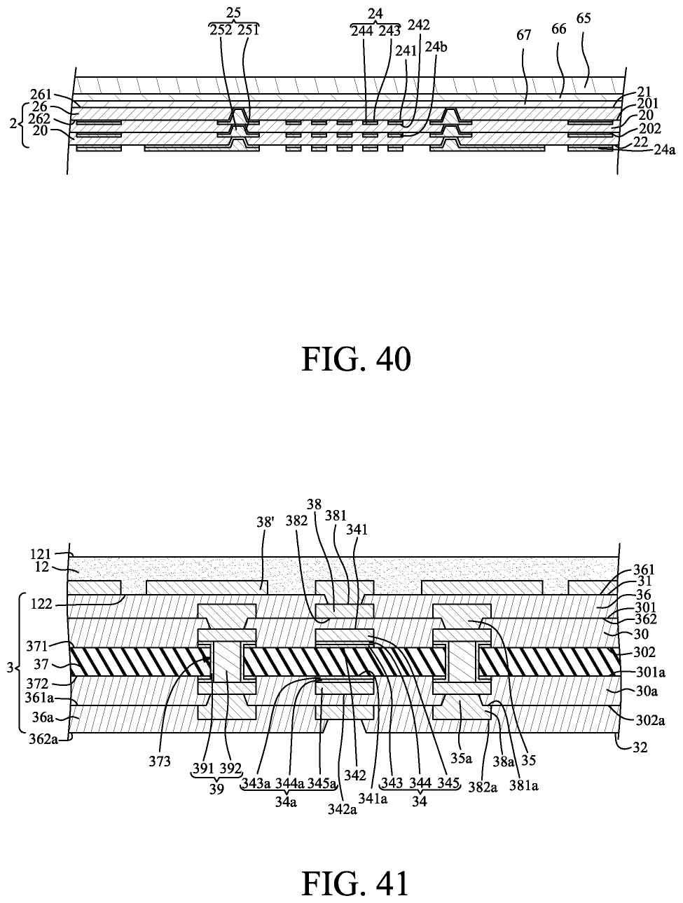

Referring to FIG. 40, a plurality of first dielectric layers 20 and a plurality of circuit layers 24 are formed by repeating the stages of FIG. 33 to FIG. 39. In some embodiments, each circuit layer 24 is embedded in the corresponding first dielectric layer 20, and a top surface 241 of the circuit layer 24 may be substantially coplanar with a top surface 201 of the first dielectric layer 20. Meanwhile, the upper conductive structure 2 is formed, and the dielectric layers (including, the first dielectric layers 20 and the second dielectric layer 26) are cured. At least one of the circuit layers (including, for example, three circuit layers 24, 24a) is in contact with at least one of the dielectric layers (e.g., the first dielectric layers 20 and the second dielectric layer 26). Then, an electrical property (such as open circuit/short circuit) of the upper conductive structure 2 is tested.

Referring to FIG. 41, an adhesive layer 12 is formed or applied on the top surface 31 of the lower conductive structure 3.

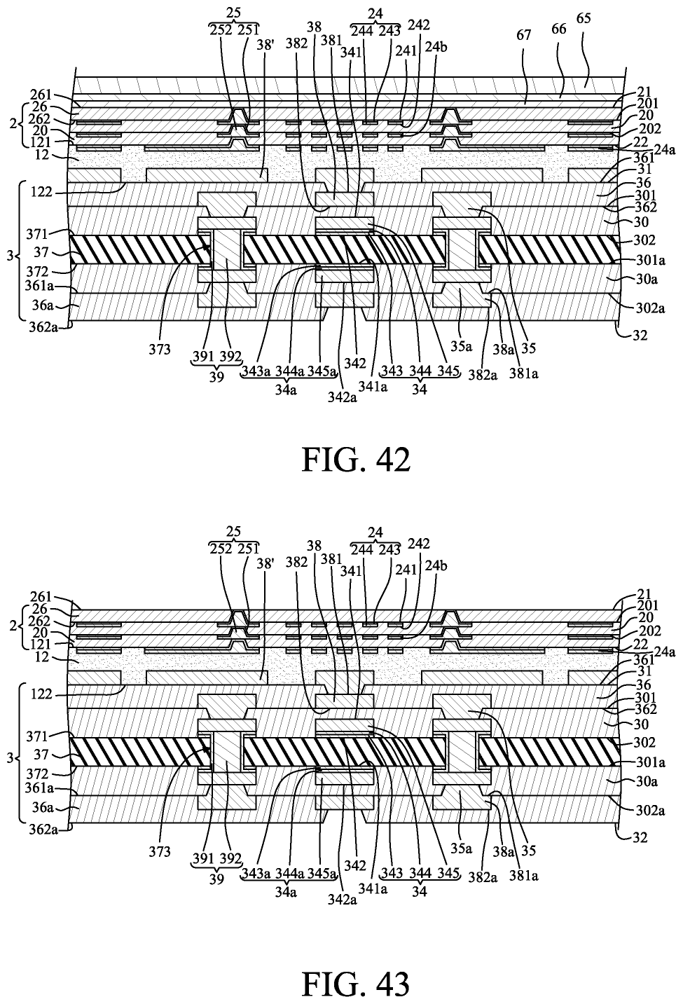

Referring to FIG. 42, the upper conductive structure 2 is attached to the lower conductive structure 3 through the adhesive layer 12. In some embodiments, the known good upper conductive structure 2 is attached to the known good lower conductive structure 3. Then, the adhesive layer 12 is cured to form an intermediate layer 12. In some embodiments, the upper conductive structure 2 may be pressed onto the lower conductive structure 3. Thus, the thickness of the intermediate layer 12 is determined by a gap between the upper conductive structure 2 and the lower conductive structure 3. The top surface 121 of the intermediate layer 12 contacts the bottom surface 22 of the upper conductive structure 2 (that is, the bottom surface 22 of the upper conductive structure 2 is attached to the top surface 121 of the intermediate layer 12), and the bottom surface 122 of the intermediate layer 12 contacts the top surface 31 of the lower conductive structure 3. Thus, the bottommost circuit layer 24a (e.g., the first circuit layer 24a) of the upper conductive structure 2 and the second upper circuit layer 38′ of the lower conductive structure 3 are embedded in the intermediate layer 12. In some embodiments, a bonding force between two adjacent dielectric layers (e.g., two adjacent first dielectric layers 20) of the upper conductive structure 2 is greater than a bonding force between a dielectric layer (e.g., the bottommost first dielectric layer 20) of the upper conductive structure 2 and the intermediate layer 12. A surface roughness of a boundary between two adjacent dielectric layers (e.g., two adjacent first dielectric layers 20) of the upper conductive structure 2 is greater than a surface roughness of a boundary between a dielectric layer (e.g., the bottommost first dielectric layer 20) of the upper conductive structure 2 and the intermediate layer 12.

Referring to FIG. 43, the carrier 65, the release layer 66 and the conductive layer 67 are removed so as to expose a portion of the inner via 25.

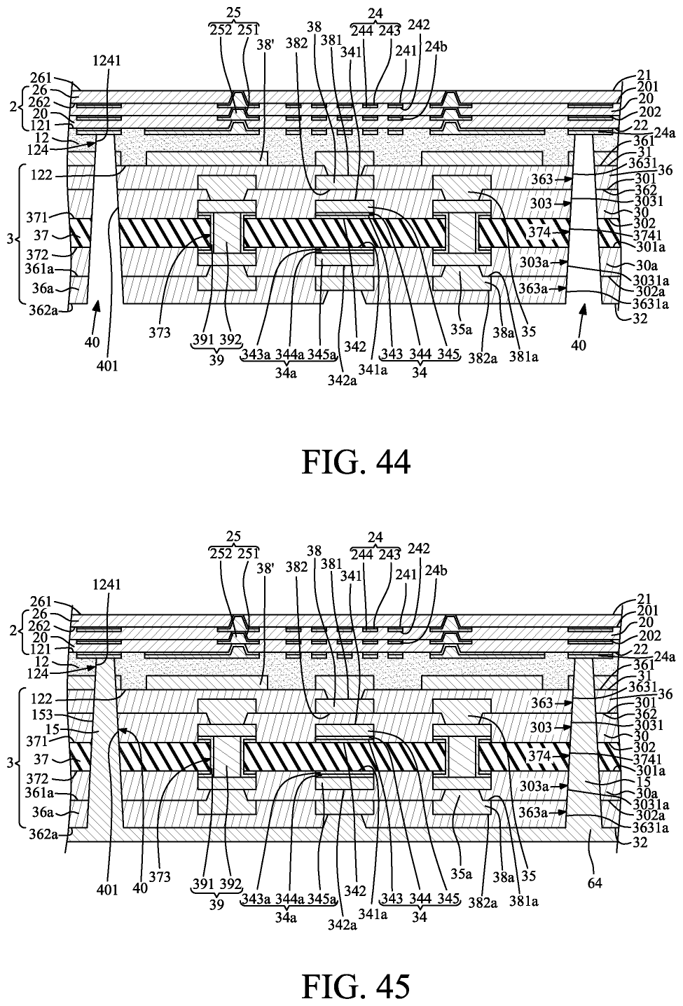

Referring to FIG. 44, at least one through hole 40 is formed to extend through at least a portion of the lower conductive structure 3 and the intermediate layer 12 by drilling (such as laser drilling) to exposes a circuit layer (e.g., the first circuit layer 24a) of the upper conductive structure 2. The through hole 40 may include a first through hole 124 of the intermediate layer 12, a through hole 363 of the second upper dielectric layer 36, a through hole 303 of the first upper dielectric layer 30, a second through hole 374 of the core portion 37, a through hole 303a of the first lower dielectric layer 30a and a through hole 363a of the second lower dielectric layer 36a. In some embodiments, the through hole 40 extends through the topmost circuit layer (e.g., the second upper circuit layer 38′) of the lower conductive structure 3 and terminates at or on the bottommost circuit layer 24a (e.g., the first circuit layer 24a) of the upper conductive structure 2. That is, the through hole 40 does not extend through the bottommost circuit layer 24a (e.g., the first circuit layer 24a) of the upper conductive structure 2. The through hole 40 may expose a portion of the bottommost circuit layer 24a (e.g., the first circuit layer 24a) of the upper conductive structure 2. As shown in FIG. 44, the through hole 40 tapers upwardly; that is, a size of a top portion of the through hole 40 is smaller than a size of a bottom portion of the through hole 40. In addition, an inner surface 1241 of the first through hole 124, an inner surface 3631 of the through hole 363, an inner surface 3031 of the through hole 303, an inner surface 3741 of the second through hole 374, an inner surface 3031a of the through hole 303a and an inner surface 3631a of the through hole 363a are coplanar or aligned with each other. Thus, cross-sectional views of one side of the inner surface 1241 of the first through hole 124, the inner surface 3631 of the through hole 363, the inner surface 3031 of the through hole 303, the inner surface 3741 of the second through hole 374, the inner surface 3031a of the through hole 303a and the inner surface 3631a of the through hole 363a are segments of a substantially straight line. That is, cross-sectional views of one side of the inner surface 1241 of the first through hole 124, the inner surface 3631 of the through hole 363, the inner surface 3031 of the through hole 303, the inner surface 3741 of the second through hole 374, the inner surface 3031a of the through hole 303a and the inner surface 3631a of the through hole 363a may extend along the same substantially straight line. That is, an inner surface 401 of the single, continuous through hole 40 may be a substantially smooth or continuous surface. The single through hole 40 tapers upwardly.

Referring to FIG. 45, a metallic layer 64 is formed on the bottom surface 32 of the lower conductive structure 3 and in the through hole 40 to form at least one lower through via 15 in the through hole 40 by a plating technique or other suitable techniques.

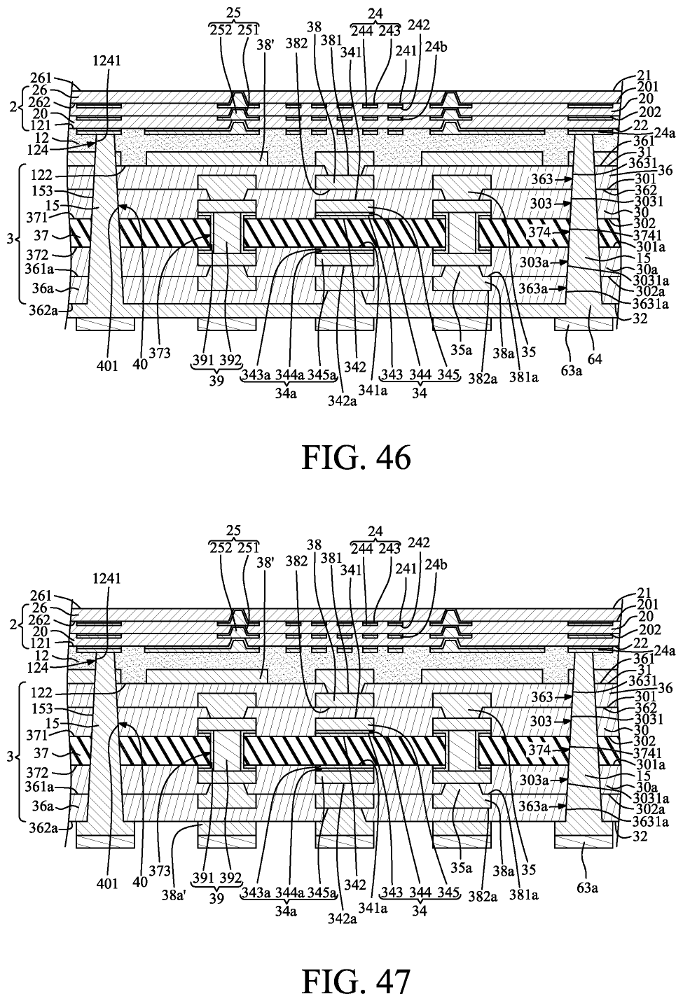

Referring to FIG. 46, a bottom photoresist layer 63a is formed or disposed on the metallic layer 64. Then, the bottom photoresist layer 63a is patterned by exposure and development.

Referring to FIG. 47, portions of the metallic layer 64 that are not covered by the bottom photoresist layer 63a are removed by an etching technique or other suitable techniques. Portions of the metallic layer 64 that are covered by the bottom photoresist layer 63a remain to form a second lower circuit layer 38a′. Then, the bottom photoresist layer 63a is removed by a stripping technique or other suitable techniques, so as to obtain the wiring structure 1 of FIG. 1. Since the upper conductive structure 2 and the lower conductive structure 3 are manufactured separately, a warpage of the upper conductive structure 2 and a warpage of the lower conductive structure 3 are separated and will not influence each other. In some embodiments, a warpage shape of the upper conductive structure 2 may be different from a warpage shape of the lower conductive structure 3. For example, the warpage shape of the upper conductive structure 2 may be a convex shape, and the warpage shape of the lower conductive structure 3 may be a concave shape. In some embodiments, the warpage shape of the upper conductive structure 2 may be the same as the warpage shape of the lower conductive structure 3; however, the warpage of the lower conductive structure 3 will not be accumulated onto the warpage of the upper conductive structure 2. Thus, the yield of the wiring structure 1 may be improved. In addition, the lower conductive structure 3 and the upper conductive structure 2 may be tested individually before being bonded together. Therefore, known good lower conductive structure 3 and known good upper conductive structure 2 may be selectively bonded together. Bad (or unqualified) lower conductive structure 3 and bad (or unqualified) upper conductive structure 2 may be discarded. As a result, the yield of the wiring structure 1 may be further improved.

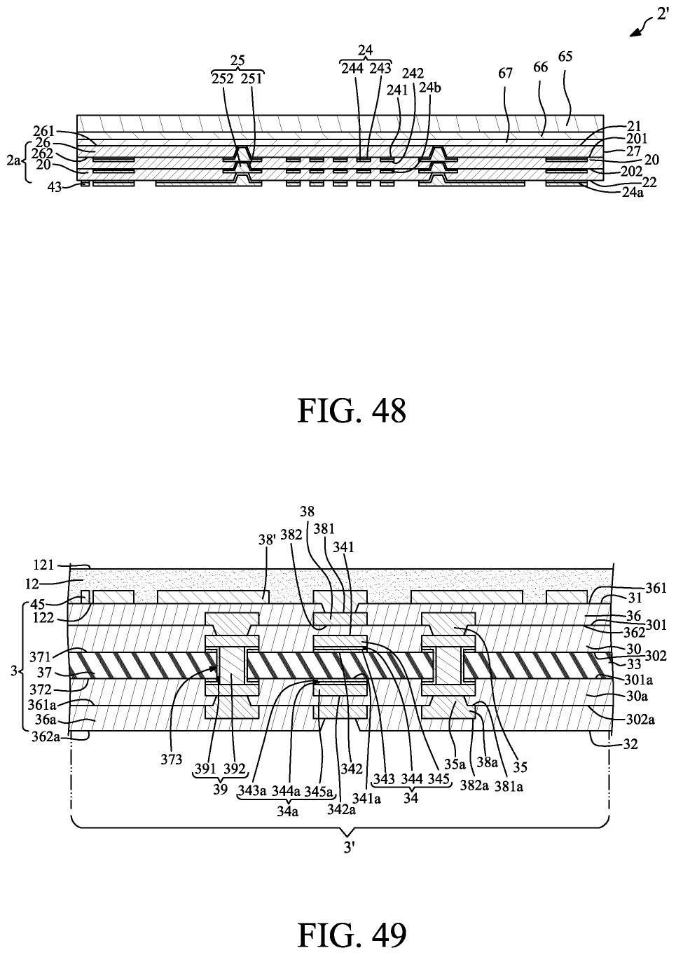

FIG. 48 through FIG. 51 illustrate a method for manufacturing a wiring structure according to some embodiments of the present disclosure. In some embodiments, the method is for manufacturing the wiring structure 1a shown in FIG. 2. The initial stages of the illustrated process are the same as, or similar to, the stages illustrated in FIG. 10 to FIG. 40. FIG. 48 depicts a stage subsequent to that depicted in FIG. 40.

Referring to FIG. 48, a fiducial mark 43 and the bottommost circuit layer 24a (e.g., the first circuit layer 24a) are formed concurrently and are at the same layer. Thus, the fiducial mark 43 is disposed on and protrudes from the bottom surface 22 of the upper conductive structure 2a. Then, the upper conductive structure 2a, the carrier 65, the release layer 66 and the conductive layer 67 are cut or singulated concurrently to form a plurality of strips 2′. Each of the strips 2′ includes the upper conductive structure 2a that is a strip structure. Then, the strips 2′ are tested. Alternatively, the upper conductive structure 2a may be tested before the cutting process.

Referring to FIG. 49, a fiducial mark 45 and the second upper circuit layer 38′ are formed concurrently and are at the same layer. Thus, the fiducial mark 45 is disposed on and protrudes from the top surface 31 of the lower conductive structure 3. The lower conductive structure 3 includes a plurality of strip areas 3′. Then, the strip areas 3′ are tested. Then, an adhesive layer 12 is formed or applied on the top surface 31 of the lower conductive structure 3.

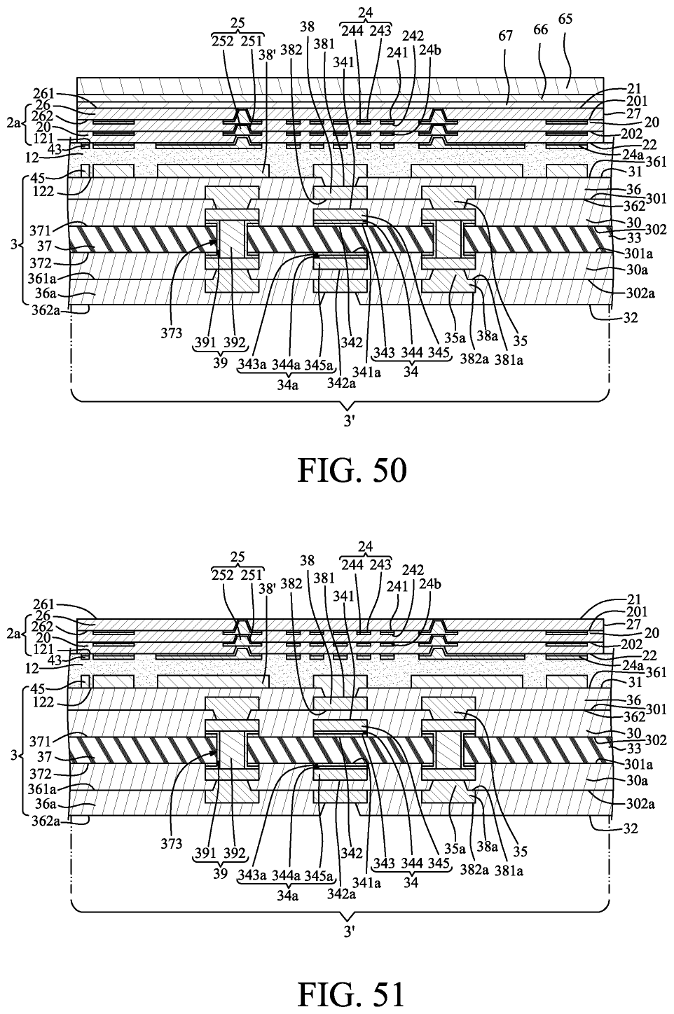

Referring to FIG. 50, the strips 2′ are attached to the strip areas 3′ of the lower conductive structure 3 through the adhesive layer 12. The upper conductive structure 2a faces and is attached to the lower conductive structure 3. During the attaching process, the fiducial mark 43 of the upper conductive structure 2a is aligned with the fiducial mark 45 of the lower conductive structure 3, so that the relative positions of the upper conductive structure 2a and the lower conductive structure 3 is secured. In some embodiments, known good strip 2′ is selectively attached to known good strip area 3′ of the lower conductive structure 3. For example, a desired yield of the wiring structure 1a (FIG. 2) may be set to be 80%. That is, (the yield of the upper conductive structure 2a)×(the yield of the strip area 3′ of the lower conductive structure 3) is set to be greater than or equal to 80%. If a yield of the upper conductive structure 2a (or strip 2′) is less than a predetermined yield such as 80% (which is specified as bad or unqualified component), then, the bad (or unqualified) upper conductive structure 2a (or strip 2′) is discarded. If a yield of the upper conductive structure 2a (or strip 2′) is greater than or equal to the predetermined yield such as 80% (which is specified as known good or qualified component), then the known good upper conductive structure 2a (or strip 2′) can be used. In addition, if a yield of the strip area 3′ of the lower conductive structure 3 is less than a predetermined yield such as 80% (which is specified as bad or unqualified component), then the bad (or unqualified) strip area 3′ is marked and will not be bonded with any strip 2′. If a yield of the strip area 3′ of the lower conductive structure 3 is greater than or equal to the predetermined yield such as 80% (which is specified as known good element or qualified component), then the known good upper conductive structure 2a (or strip 2′) can be bonded to the known good strip area 3′ of the lower conductive structure 3. It is noted that the upper conductive structure 2a (or strip 2′) having a yield of 80% will not be bonded to the strip area 3′ of the lower conductive structure 3 having a yield of 80%, since the resultant yield of the wiring structure 1a (FIG. 2) is 64%, which is lower than the desired yield of 80%. The upper conductive structure 2a (or strip 2′) having a yield of 80% can be bonded to the strip area 3′ of the lower conductive structure 3 having a yield of 100%; thus, the resultant yield of the wiring structure la (FIG. 2) can be 80%. In addition, an upper conductive structure 2a (or strip 2′) having a yield of 90% can be bonded to the strip area 3′ of the lower conductive structure 3 having a yield of greater than 90%, since the resultant yield of the wiring structure 1a (FIG. 2) can be greater than 80%.

Referring to FIG. 51, the adhesive layer 12 is cured to form the intermediate layer 12. Then, the carrier 65, the release layer 66 and the conductive layer 67 are removed. Then, the stages subsequent to that shown in FIG. 51 of the illustrated process are similar to the stages illustrated in FIG. 44 to FIG. 47. Then, the lower conductive structure 3 and the intermediate layer 12 are cut along the strip areas 3′, so as to obtain the wiring structure 1a of FIG. 2.

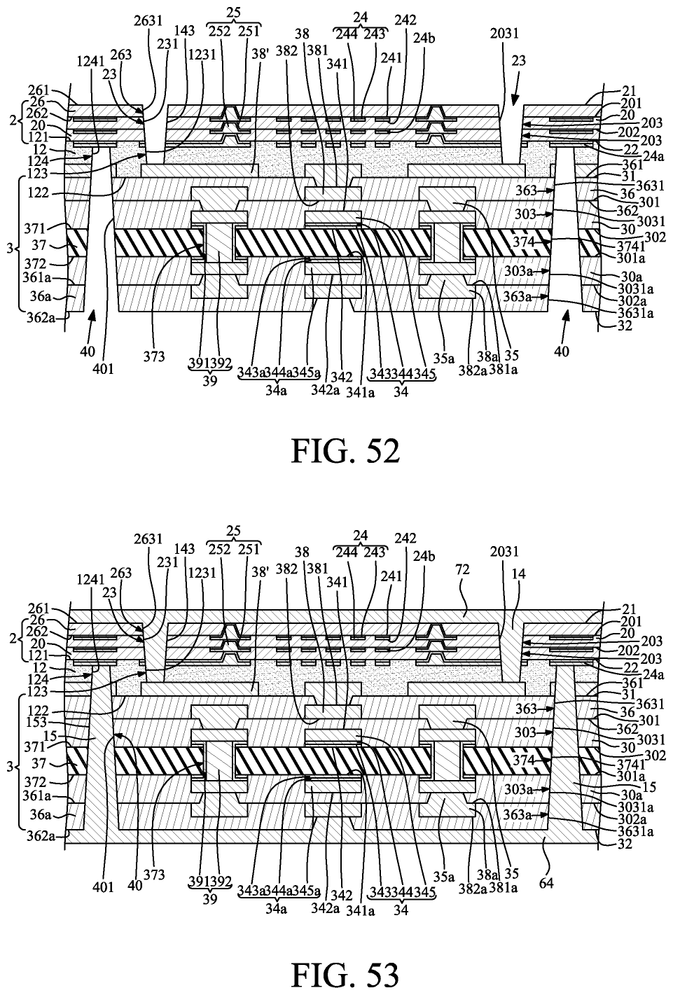

FIG. 52 through FIG. 55 illustrate a method for manufacturing a wiring structure according to some embodiments of the present disclosure. In some embodiments, the method is for manufacturing the wiring structure 1b shown in FIG. 3. The initial stages of the illustrated process are the same as, or similar to, the stages illustrated in FIG. 10 to FIG. 43. FIG. 52 depicts a stage subsequent to that depicted in FIG. 43.

Referring to FIG. 52, at least one through hole 23 is formed to extend through at least a portion of the upper conductive structure 2 and the intermediate layer 12 by drilling (such as laser drilling) to exposes a circuit layer (e.g., the second upper circuit layer 38′) of the lower conductive structure 3. Meanwhile, at least one through hole 40 is formed to extend through at least a portion of the lower conductive structure 3 and the intermediate layer 12 by drilling (such as laser drilling) to exposes a circuit layer (e.g., the first circuit layer 24a) of the upper conductive structure 2. The through hole 23 may include a first through hole 123 of the intermediate layer 12, a through hole 263 of the second dielectric layer 26, and a plurality of through holes 203 of the first dielectric layers 20. In some embodiments, the through hole 23 extends through the bottommost circuit layer 24a (e.g., the first circuit layer 24a) of the upper conductive structure 2 and terminates at or on a topmost circuit layer (e.g., the second upper circuit layer 38′) of the lower conductive structure 3. That is, the through hole 23 does not extend through the topmost circuit layer (e.g., the second upper circuit layer 38′) of the lower conductive structure 3. The through hole 23 may expose a portion of the topmost circuit layer (e.g., the top surface of the second upper circuit layer 38′) of the lower conductive structure 3. As shown in FIG. 52, the through hole 23 tapers downwardly; that is, a size of a top portion of the through hole 23 is greater than a size of a bottom portion of the through hole 23. In addition, the inner surface 1231 of the through hole 123 of the intermediate layer 12 is coplanar with or aligned with the inner surfaces 2031 of the through holes 203 of the first dielectric layers 20 and the inner surface 2631 of the through hole 263 of the second dielectric layer 26. Thus, cross-sectional views of one side of the inner surface 1231 of the through hole 123 of the intermediate layer 12, the inner surfaces 2031 of the through holes 203 of the first dielectric layers 20 and the inner surface 2631 of the through hole 263 of the second dielectric layer 26 are segments of a substantially straight line. That is, cross-sectional views of one side of the inner surface 1231 of the through hole 123 of the intermediate layer 12, the inner surfaces 2031 of the through holes 203 of the first dielectric layers 20 and the inner surface 2631 of the through hole 263 of the second dielectric layer 26 may extend along the same substantially straight line. That is, the inner surface 231 of the single, continuous through hole 23 may be a substantially smooth or continuous surface. The single through hole 23 tapers downwardly. A maximum width of the single through hole 23 (e.g., at the top portion) may be about 25 μm to about 60 μm. The through hole 40 may be the same as, or similar to, the through hole 40 of FIG. 44.

Referring to FIG. 53, a metallic layer 72 is formed on the top surface 21 of the upper conductive structure 2 and in the through hole 23 to form at least one upper through via 14 in the through hole 23 by a plating technique or other suitable techniques. Meanwhile, a metallic layer 64 is formed on the bottom surface 32 of the lower conductive structure 3 and in the through hole 40 to form at least one lower through via 15 in the through hole 40 by a plating technique or other suitable techniques.

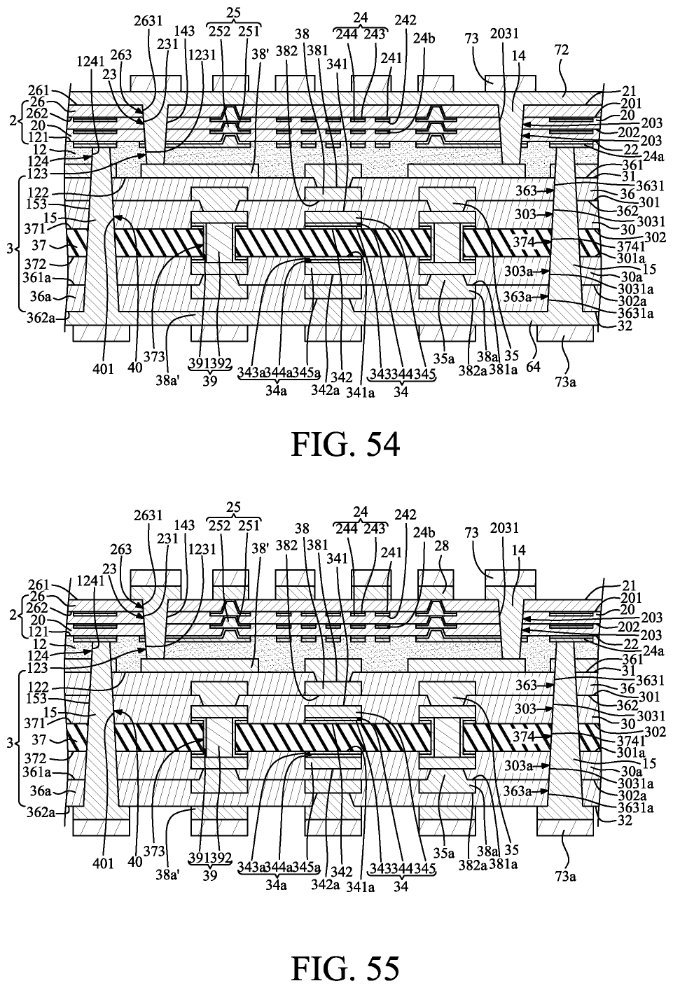

Referring to FIG. 54, a top photoresist layer 73 is formed or disposed on the metallic layer 72, and a bottom photoresist layer 73a is formed or disposed on the metallic layer 64. Then, the top photoresist layer 73 and the bottom photoresist layer 73a are patterned by an exposure and development technique or other suitable techniques.

Referring to FIG. 55, portions of the metallic layer 72 that are not covered by the top photoresist layer 73 are removed by an etching technique or other suitable techniques. Portions of the metallic layer 72 that are covered by the top photoresist layer 73 remain to form an outer circuit layer 28. Meanwhile, portions of the metallic layer 64 that are not covered by the bottom photoresist layer 73a are removed by an etching technique or other suitable techniques. Portions of the metallic layer 64 that are covered by the bottom photoresist layer 73a remain to form a second lower circuit layer 38a′. Then, the top photoresist layer 73 and the bottom photoresist layer 73a are removed by a stripping technique or other suitable techniques, so as to obtain the wiring structure 1b of FIG. 3.

In some embodiments, a semiconductor chip 42 (FIG. 5) is electrically connected and bonded to the outer circuit layer 28 of the upper conductive structure 2 through a plurality of first connecting elements 44 (e.g., solder bumps or other conductive bumps). Then, the upper conductive structure 2, the intermediate layer 12 and the lower conductive structure 3 are singulated concurrently, so as to from a package structure 4 as shown in FIG. 5. The package structure 4 includes a wiring structure 1d and the semiconductor chip 42. The wiring structure 1d of FIG. 5 includes a singulated upper conductive structure 2d and a singulated lower conductive structure 3d. That is, a lateral peripheral surface 27d of the upper conductive structure 2d, a lateral peripheral surface 33d of the lower conductive structure 3d and a lateral peripheral surface of the intermediate layer 12 are substantially coplanar with each other. Then, the second upper circuit layer 38′ of the lower conductive structure 3d is electrically connected and bonded to the substrate 46 (e.g., a mother board such as a PCB) through a plurality of second connecting elements 48 (e.g., solder bumps or other conductive bumps).

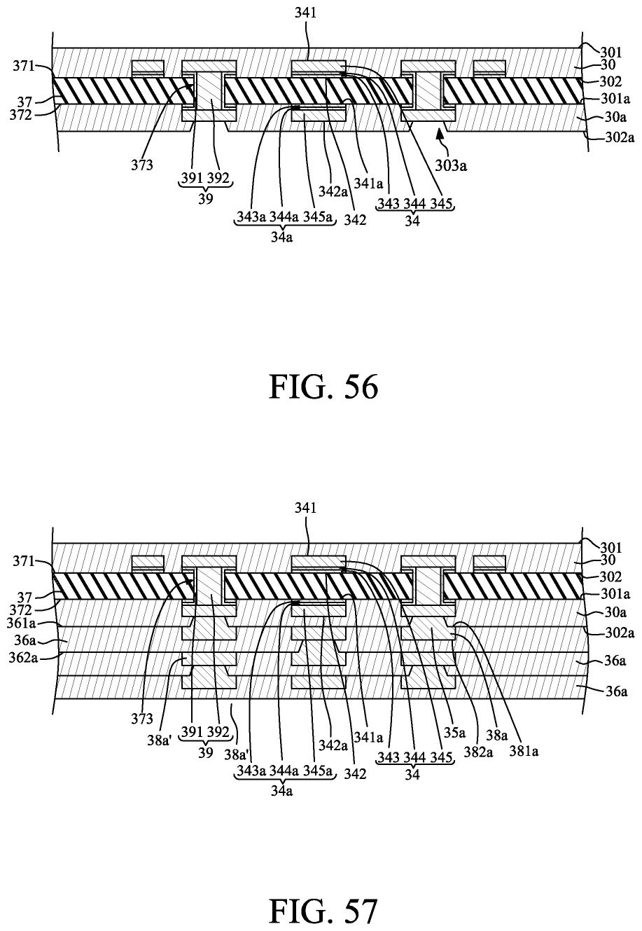

FIG. 56 through FIG. 63 illustrate a method for manufacturing a wiring structure according to some embodiments of the present disclosure. In some embodiments, the method is for manufacturing the wiring structure 1e shown in FIG. 6. The initial stages of the illustrated process are the same as, or similar to, the stages illustrated in FIG. 10 to FIG. 18. FIG. 56 depicts a stage subsequent to that depicted in FIG. 18.

Referring to FIG. 56 through FIG. 58, a lower conductive structure 3e is provided. The lower conductive structure 3e is manufactured as follows. Referring to FIG. 56, at least one through hole 303a is formed to extend through the first lower dielectric layer 30a to expose a portion of the first lower circuit layer 34a by a drilling technique or other suitable techniques. It is noted that no through hole is formed in the first upper dielectric layer 30.

Referring to FIG. 57, a second lower circuit layer 38a is formed or disposed on the first lower dielectric layer 30a. Then, three second lower dielectric layers 36a and two second lower circuit layers 38a′ are formed or disposed on the first lower dielectric layer 30a.

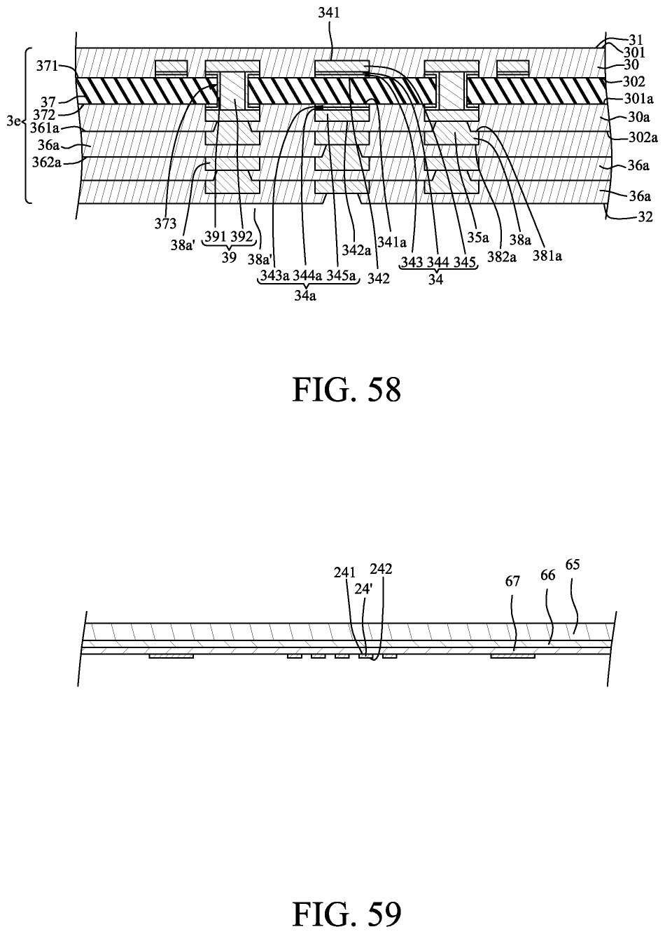

Referring to FIG. 58, the bottommost lower circuit layer 38a′ is formed or disposed on the bottommost second lower dielectric layer 36a, so as to obtain the lower conductive structure 3e. In the lower conductive structure 3e, the top surface 31 of the lower conductive structure 3e is the top surface 301 of first upper dielectric layer 30, which is substantially flat.

Referring to FIG. 59 through FIG. 62, an upper conductive structure 2e is provided. The upper conductive structure 2e is manufactured as follows. Referring to FIG. 59, a carrier 65 is provided. A release layer 66 is coated on the bottom surface of the carrier 65. A conductive layer 67 (e.g., a seed layer) is formed or disposed on the release layer 66 by a PVD technique or other suitable techniques. Then, a topmost circuit layer 24′ is formed on the conductive layer 67.

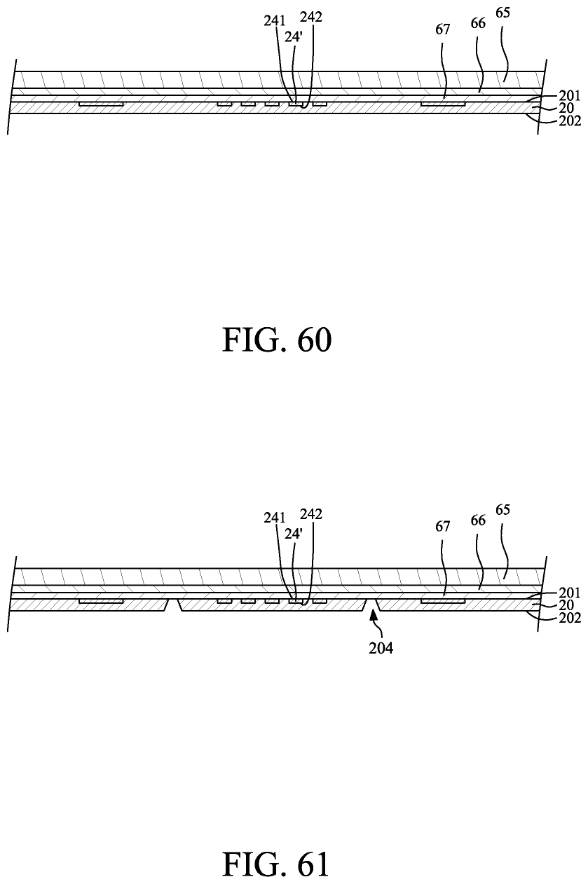

Referring to FIG. 60, a topmost first dielectric layer 20 is formed on the conductive layer 67 by a coating technique or other suitable techniques, so as to cover the topmost circuit layer 24′.

Referring to FIG. 61, at least one through hole 204 is formed to extend through the topmost first dielectric layer 20 to expose a portion of the conductive layer 67 by an exposure and development technique or other suitable techniques.

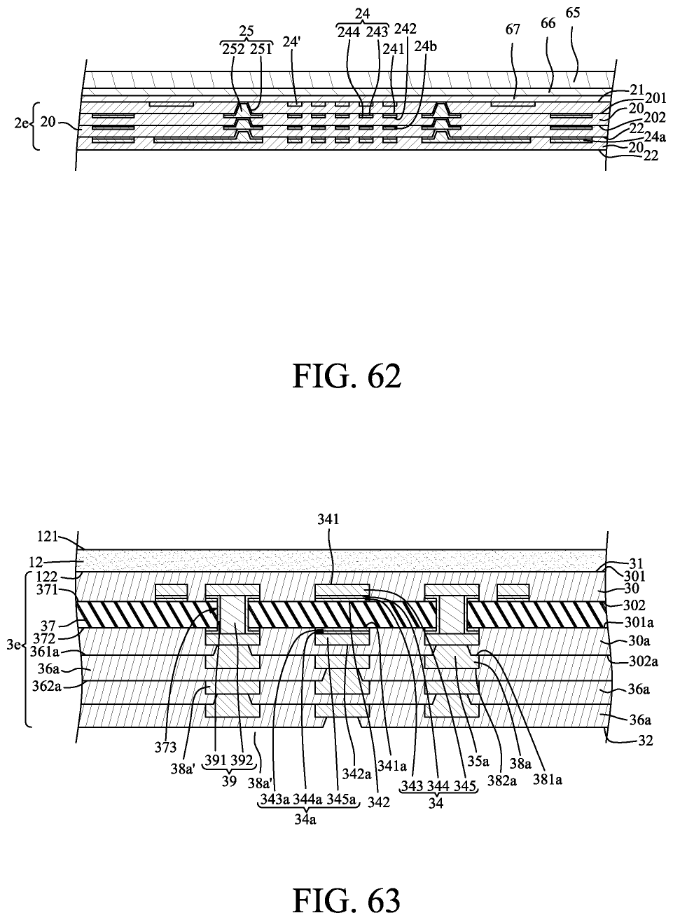

Referring to FIG. 62, a plurality of first dielectric layers 20, a plurality of circuit layers 24 and a plurality of inner vias 25 are formed on the topmost first dielectric layer 20, so as to obtain the upper conductive structure 2e. As shown in FIG. 62, the bottommost first dielectric layer 20 may cover the bottommost circuit layer 24a (e.g., the first circuit layer 24a). Thus, the entire bottom surface 22 of the upper conductive structure 2e (e.g., the bottom surface 202 of the bottommost first dielectric layer 20) is substantially flat.

Referring to FIG. 63, an adhesive layer 12 is formed or applied on the top surface 31 of the lower conductive structure 3e.

Then, the following stages of the illustrated process are the same as, or similar to, the stages illustrated in FIG. 42 to FIG. 47, as described below. The upper conductive structure 2e is attached to the lower conductive structure 3e through the adhesive layer 12. Then, the adhesive layer 12 is cured to form the intermediate layer 12. The intermediate layer 12 adheres to the bottom surface 22 of the upper conductive structure 2e and the top surface 31 of the lower conductive structure 3e. Thus, the entire top surface 121 and the entire bottom surface 122 of the intermediate layer 12 are both substantially flat. The intermediate layer 12 does not include or contact a horizontally extending or connecting circuit layer. That is, there is no horizontally extending or connecting circuit layer disposed in or embedded in the intermediate layer 12.

Then, the carrier 65, the release layer 66 and the conductive layer 67 are removed so as to expose a portion of the inner via 25, a portion of the topmost circuit layer 24′ and the topmost first dielectric layer 20. The top surface 241 of the topmost circuit layer 24′ may be substantially coplanar with the top surface 201 of the topmost first dielectric layer 20.

Then, the lower through via 15 is formed so as to obtain the wiring structure le of FIG. 6.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A wiring structure, comprising:
an upper conductive structure including at least one upper dielectric layer and at least one upper circuit layer in contact with the upper dielectric layer;
a lower conductive structure including at least one lower dielectric layer and at least one lower circuit layer in contact with the lower dielectric layer;
an intermediate layer disposed between the upper conductive structure and the lower conductive structure and bonding the upper conductive structure and the lower conductive structure together; and
at least one lower through via extending through at least a portion of the lower conductive structure and the intermediate layer, and electrically connected to the upper circuit layer of the upper conductive structure.

2. The wiring structure of claim 1, wherein the upper conductive structure includes a plurality of upper dielectric layers including the upper dielectric layer, a plurality of upper circuit layers including the upper circuit layer, and at least one inner via disposed between two adjacent ones of the upper circuit layers for electrically connecting the two adjacent ones of the upper circuit layers, the inner via tapers upwardly, and the lower through via tapers upwardly.

3. The wiring structure of claim 1, wherein the upper conductive structure includes a plurality of upper dielectric layers including the upper dielectric layer, a plurality of upper circuit layers including the upper circuit layer, and at least one inner via disposed between two adjacent ones of the upper circuit layers for electrically connecting the two adjacent ones of the upper circuit layers, a tapering direction of the inner via is the same as a tapering direction of the lower through via.

4. The wiring structure of claim 1, wherein a material of the upper dielectric layer of the upper conductive structure and a material of the intermediate layer are transparent.

5. The wiring structure of claim 1, wherein the lower conductive structure includes a plurality of stacked lower dielectric layers including the lower dielectric layer, each of the lower dielectric layers defines a through hole having an inner surface, the intermediate layer defines a through hole having an inner surface, and the inner surface of the through hole of the intermediate layer and the inner surfaces of the through holes of the lower dielectric layers are coplanar with each other.

6. The wiring structure of claim 1, wherein the lower conductive structure includes a plurality of stacked lower dielectric layers including the lower dielectric layer, each of the lower dielectric layers defines a through hole, the intermediate layer defines a through hole, and the through hole of the intermediate layer and the through holes of the lower dielectric layers collectively define a single through hole for accommodating the lower through via.

7. The wiring structure of claim 1, wherein the lower dielectric layer defines a through hole including a top portion having a first size, and the intermediate layer defines a through hole including a bottom portion having a second size that is substantially equal to the first size.

8. The wiring structure of claim 1, wherein the lower through via extends to contact a portion of the upper conductive structure.

9. The wiring structure of claim 1, wherein the upper circuit layer is a bottommost circuit layer of the upper conductive structure, and the lower through via contacts the bottommost circuit layer of the upper conductive structure.

10. The wiring structure of claim 1, wherein the lower through via is a monolithic structure.

11. The wiring structure of claim 1, wherein a peripheral surface of the lower through via is a continuous surface.

12. The wiring structure of claim 1, wherein the intermediate layer has a top surface and a bottom surface, and the entire top surface and the entire bottom surface of the intermediate layer are substantially flat.

13. The wiring structure of claim 1, wherein the upper conductive structure includes a plurality of upper dielectric layers including the upper dielectric layer, a bonding force between two adjacent ones of the upper dielectric layers of the upper conductive structure is greater than a bonding force between a bottommost one of the upper dielectric layers of the upper conductive structure and the intermediate layer.

14. The wiring structure of claim 1, wherein the upper conductive structure includes a plurality of upper dielectric layers including the upper dielectric layer, a surface roughness of a boundary between two adjacent ones of the upper dielectric layers of the upper conductive structure is greater than a surface roughness of a boundary between a bottommost one of the upper dielectric layers of the upper conductive structure and the intermediate layer.

15. The wiring structure of claim 1, wherein a line space of the lower circuit layer of the lower conductive structure is greater than a line space of the upper circuit layer of the upper conductive structure.

16. The wiring structure of claim 1, further comprising:
at least one upper through via extending through at least a portion of the upper conductive structure and the intermediate layer, and electrically connected to the lower circuit layer of the lower conductive structure.

17. The wiring structure of claim 16, wherein the upper conductive structure includes a plurality of upper dielectric layers including the upper dielectric layer, a plurality of upper circuit layers including the upper circuit layer, and at least one inner via disposed between two adjacent ones of the upper circuit layers for electrically connecting the two adjacent ones of the upper circuit layers, the inner via tapers upwardly, and the upper through via tapers downwardly.

18. The wiring structure of claim 16, wherein the upper conductive structure includes a plurality of upper dielectric layers including the upper dielectric layer, a plurality of upper circuit layers including the upper circuit layer, and at least one inner via disposed between two adjacent ones of the upper circuit layers for electrically connecting the two adjacent ones of the upper circuit layers, a tapering direction of the inner via is different from a tapering direction of the upper through via.

19. The wiring structure of claim 16, wherein the upper conductive structure includes a plurality of stacked upper dielectric layers including the upper dielectric layer, each of the upper dielectric layers defines a through hole having an inner surface, the intermediate layer defines a through hole having an inner surface, and the inner surface of the through hole of the intermediate layer and the inner surfaces of the through holes of the upper dielectric layers are coplanar with each other.

20. The wiring structure of claim 16, wherein the upper conductive structure includes a plurality of stacked upper dielectric layers including the upper dielectric layer, each of the upper dielectric layers defines a through hole, the intermediate layer defines a through hole, and the through hole of the intermediate layer and the through holes of the upper dielectric layers collectively define a single through hole for accommodating the upper through via.

21. The wiring structure of claim 16, wherein the upper dielectric layer defines a through hole including a bottom portion having a first size, and the intermediate layer defines a through hole including a top portion having a second size that is substantially equal to the first size.

22. The wiring structure of claim 16, wherein the upper through via extends to contact a portion of the lower conductive structure.

23. The wiring structure of claim 16, wherein the lower circuit layer is a topmost circuit layer of the lower conductive structure, and the upper through via contacts the topmost circuit layer of the lower conductive structure.

24. The wiring structure of claim 16, wherein the upper through via is a monolithic structure.

25. The wiring structure of claim 16, wherein a peripheral surface of the upper through via is a continuous surface.

26. A wiring structure, comprising:
a low-density stacked structure including at least one dielectric layer and at least one low-density circuit layer in contact with the dielectric layer;
a high-density stacked structure disposed on the low-density stacked structure, wherein the high-density stacked structure includes at least one dielectric layer and at least a first high-density circuit layer in contact with the dielectric layer of the high-density stacked structure; and
at least one lower through via extending through at least a portion of the low-density stacked structure, and terminating at the first high-density circuit layer of the high-density stacked structure.

27. The wiring structure of claim 26, wherein the high-density stacked structure further includes a second high-density circuit layer, and a thickness of the first high-density circuit layer is greater than a thickness of the second high-density circuit layer.

28. The wiring structure of claim 26, wherein the high-density stacked structure includes a plurality of high-density circuit layers including the first high-density circuit layer, and at least one of the high-density circuit layers includes one or more high-density traces and a ground plane.

29. The wiring structure of claim 26, wherein the low-density circuit layer of the low-density stacked structure includes one or more low-density traces and a ground plane.

30. The wiring structure of claim 26, wherein the low-density circuit layer of the low-density stacked structure is electrically connected to the first high-density circuit layer of the high-density stacked structure by the lower through via extending through the low-density circuit layer of the low-density stacked structure.

31. The wiring structure of claim 26, wherein a length of the lower through via is greater than a thickness of the low-density stacked structure.

32. The wiring structure of claim 26, wherein a lateral surface of the low-density stacked structure is displaced from a lateral surface of the high-density stacked structure.

33. The wiring structure of claim 26, wherein the high-density stacked structure includes a fiducial mark, the low-density stacked structure includes a fiducial mark, and the fiducial mark of the high-density stacked structure is aligned with the fiducial mark of the low-density stacked structure.

34. The wiring structure of claim 26, wherein a warpage shape of the high-density stacked structure is different from a warpage shape of the low-density stacked structure.

35. The wiring structure of claim 26, further comprising:
a bottommost low-density circuit layer disposed on a bottom surface of the low-density stacked structure.

36. The wiring structure of claim 35, wherein a line space of the bottommost low-density circuit layer is substantially equal to a line space of the low-density circuit layer of the low-density stacked structure.

37. The wiring structure of claim 26, further comprising:
an intermediate layer disposed between the low-density stacked structure and the high-density stacked structure, wherein the lower through via further extends through the intermediate layer.

38. The wiring structure of claim 37, wherein the low-density circuit layer is a topmost low-density circuit layer of the low-density stacked structure, the first high-density circuit layer is a bottommost high-density circuit layer of the high-density stacked structure, and the topmost low-density circuit layer of the low-density stacked structure and the bottommost high-density circuit layer of the high-density stacked structure are embedded in the intermediate layer.

39. The wiring structure of claim 26, further comprising:
at least one upper through via extending through at least a portion of the high-density stacked structure, and terminating on the low-density circuit layer of the low-density stacked structure.

40. The wiring structure of claim 39, further comprising:
a top low-density circuit layer disposed on a top surface of the high-density stacked structure, wherein the top low-density circuit layer and the upper through via are formed integrally.

41. The wiring structure of claim 39, wherein the upper through via is disposed in a low-density region of the high-density stacked structure.

42. The wiring structure of claim 39, wherein a size of an end portion of the upper through via is substantially equal to a size of an end portion of the lower through via.

43. A method for manufacturing a wiring structure, comprising:
(a) providing a lower conductive structure including at least one dielectric layer and at least one circuit layer in contact with the dielectric layer;
(b) providing an upper conductive structure including at least one dielectric layer and at least one circuit layer in contact with the dielectric layer of the upper conductive structure;
(c) attaching the upper conductive structure to the lower conductive structure; and
(d) electrically connecting the upper conductive structure and the lower conductive structure.

44. The method of claim 43, wherein (b) comprises:
(b1) forming the upper conductive structure on a carrier; and
(b2) cutting the upper conductive structure and the carrier;
wherein in (c), the upper conductive structure and the carrier are attached to the lower conductive structure, wherein the upper conductive structure faces the lower conductive structure;
wherein after (c), the method further comprises:
(c1) removing the carrier.

45. The method of claim 43, wherein after (a), the method further comprises:
(a1) testing an electrical property of the lower conductive structure; and
wherein after (b), the method further comprises:
(b1) testing an electrical property of the upper conductive structure.

46. The method of claim 43, wherein in (c), the upper conductive structure is attached to the lower conductive structure through an adhesive layer.

47. The method of claim 46, wherein (d) includes:
(d1) forming at least one through hole to extend through at least a portion of the lower conductive structure and the adhesive layer, wherein the through hole exposes a circuit layer of the upper conductive structure; and
(d2) forming at least one lower through via in the through hole to contact the circuit layer of the upper conductive structure.
